(19) United States
(12) Patent Application Publication
(10) Pub. No.: US 2016/0137533 A1
(43) Pub. Date: May 19, 2016

(54) BINDER-FREE CARBON NANOTUBE ELECTRODE FOR ELECTROCHEMICAL REMOVAL OF CHROMIUM

(71) Applicant: University of Notre Dame du Lac, Notre Dame, IN (US)

(72) Inventors: Chongzheng Na, South Bend, IN (US); Haitao Wang, Notre Dame, IN (US)

(21) Appl. No.: 14/941,447

(22) Filed: Nov. 13, 2015

Related U.S. Application Data
(60) Provisional application No. 62/079,789, filed on Nov. 14, 2014.

(51) Int. Cl. C02F 1/461; C23C 16/44; C23C 16/06

(52) U.S. Cl. CPC C02F 1/46109; C23C 16/06; C23C 16/44; C02F 2001/46142; C02F 2101/20

(57) ABSTRACT

Electrochemical treatment of chromium-containing wastewater has the advantage of simultaneously reducing hexavalent chromium (Cr^{VI}) and reversibly adsorbing the trivalent product (Cr^{III}), thereby minimizing the generation of waste for disposal and providing an opportunity for resource reuse. The application of electrochemical treatment of chromium can be often limited by the available electrochemical surface area (ESA) of conventional electrodes with flat surfaces. Here, the preparation and evaluation of carbon nanotube (CNT) electrodes containing of vertically aligned CNT arrays directly grown on stainless steel mesh (SSM). The 3-D organization of CNT arrays increases ESA up to 13 times compared to SSM. The increase of ESA can be correlated with the length of CNTs, consistent with a mechanism of roughness-induced ESA enhancemen, and the increase directly benefits Cr^{VI} reduction by proportionally accelerating reduction without compromising the electrode's ability to adsorb Cr^{III}. The results suggest that the rational design of electrodes with hierarchical structures represents a feasible approach to improve the performance of electrochemical treatment of contaminated water.

### INCORPORATION BY REFERENCE TO RELATED APPLICATIONS

Any and all priority claims identified in the Application Data Sheet, or any correction thereto, are hereby incorporated by reference under 37 CFR 1.57. The present application claims the benefit under 35 U.S.C. §119(e) of U.S. Provisional Patent Application No. 62/079,789, filed on Nov. 14, 2014. The aforementioned application is incorporated by reference herein in its entirety, and is hereby expressly made a part of this specification.

### STATEMENT REGARDING FEDERALLY SPONSORED R&D

This invention was made with government support under CBET-1033848 awarded by the National Science Foundation and CFP-12-3923 awarded by the Department of Energy. The government has certain rights in the invention.

### FIELD OF THE INVENTION

The present application relates generally to the production of carbon nanotubes (CNTs) for water treatment. Specifically, growing vertically aligned multiwall CNTs on mesh or screen for use in certain embodiments as a catalyst substrate or as a replacement for activated carbon.

### BACKGROUND OF THE INVENTION

Chromium (Cr) is widely used in manufacturing dyes and paints, chrome plating, and leather tanning and thus is a major pollutant of the waste streams generated by these industrial processes. Inappropriate disposal of chromium can contaminate the receiving water body, particularly when chromium exists in the hexavalent state (Cr^{VI}) as chromate (CrO₄²⁻) and dichromate (Cr₂O₇²⁻). Both anions are nonbiodegradable carcinogens and highly mobile with surface and ground waters. The discharge of chromium is regulated at least in developed counties (for example, below 50 μg L⁻¹ in the United States). Traditional decontamination of Cr^{VI}-containing wastewater often involves two steps. First, Cr^{VI} is reduced to trivalent chromium (Cr^{III}) by iron or sulfide:

CrO₄²⁻+8H⁺+3e⁻=Cr³⁺+4H₂O (1)

Second, Cr^{III} is separated from water by precipitation or sorption, taking the advantage of the low solubility of Cr^{III} (also less toxic). The two-step treatment is often considered more efficient and economical than single-step separation methods such as adsorption, ion exchange, reverse osmosis, and membrane filtration. The disadvantage of the two-step method is the production of a large quantity of sludge, and spent adsorbent, still requiring disposal. The electrochemical treatment of Cr^{VI}-contaminated water can reduce Cr^{VI} to Cr^{III} and then separate it from water without producing sludge or spent adsorbent. To do so, the working electrode is negatively polarized to provide electrons for Cr^{VI} reduction and then adsorb Cr^{III} cations through electrostatic attraction. The electrode can be regenerated by reversing the polarization, which releases Cr^{III} for recollection and reuse. The constraint of the electrochemical treatment is the slow kinetics for Cr^{VI} reduction because the negatively polarized electrode repulses Cr^{VI} anions. The kinetics of Cr^{VI} reduction can be substantially improved by increasing the electrochemical surface area (ESA) of the electrode, which represents the area of the electrode's surface that can participate in an electrochemical process. One proposed strategy for increasing ESA is depositing nanomaterials such as CNTs on a glass carbon electrode. To do so, polymer binders such as poly(vinylene fluoride) and Nafion are often required to deposit an adequate amount of nanomaterials. The use of binders can, however, lead to structural disintegration under chemical attacks, reduced electrical conductivity, and increased mass-transfer resistance.

Presented herein, is a method for the design and fabrication of a binder-free CNT electrode by growing vertically aligned CNTs (VACNT) on stainless steel mesh (SSM). Note that a variety of other materials may be used including, but not limited to, other metallic surfaces or non-metallic surfaces such as a ceramic, silicon, silicon oxide, glass, cement, or carbon and silicon based polymers. However, it is noted that by using SSM, the growth of VACNTs increases ESA by more than an order of magnitude. The increased ESA can directly benefit Cr^{VI} reduction by proportionally accelerating the reduction rate without compromising the ability to adsorb Cr^{III}.

The water treatment industry is constantly driven to find more sustainable solutions to treatment problems. Cation exchange water softeners are extremely effective at removing hardness, but are under attack in several states due to the salt and water they discharge during regeneration. Reverse osmosis systems are effective at removing a total dissolved solids (TDS), but a significant percentage of the influent water is discharged to the drain as wastewater.

Electrochemical water treatment systems are emerging as a potential solution because they reduce both hardness and TDS without the use of salt at a relatively high efficiency rate. The technology goes by several names: continuous electrolytic deionization, capacitive deionization, or electrically regenerated ion exchange.

### SUMMARY OF THE INVENTION

The systems, methods, and devices of the invention each have several aspects, no single one of which is solely responsible for its desirable attributes. Without limiting the scope of this invention as expressed by the claims which follow, some features will now be discussed briefly. After considering this discussion, and particularly after reading the section entitled “Detailed Description” one will understand how the features of this invention provide advantages.

One innovation includes a composition for removing heavy metals from wastewater, comprising a binder-free electrode comprising, an oxide buffer layer, a substrate comprising a material constructed in a pattern, and a layer of catalyst nanoparticles, and an array of vertically aligned carbon nanotubes grown on the electrode.

Such an innovation may include other aspects. For example, the composition may further comprise a negatively polarized electrode configured to provide electrons for CrVI reduction and CrIII absorption through electrostatic attraction. In another aspect, the oxide buffer layer is an aluminum oxide. In another aspect, the oxide buffer layer is formed by immersion of the substrate in both (a) a polyacrylic acid solution, and (b) a boehmite (γ-AlOOH) nanoplate suspension. In another aspect, the substrate comprises a porous stainless steel mesh, the stainless steel mesh comprising a plurality of stainless steel wires, the wires having a curved surface. In another aspect, the catalyst nanoparticles are deposited on the oxide buffer layer. In another aspect, the catalyst nanoparticles comprise magnetite (Fe3O4) nanoparticles.

Another innovation includes a method of manufacturing the composition comprising cleaning a substrate, coating the substrate with the oxide buffer, depositing a layer of catalyst nanoparticles onto the oxide buffer layer layer, whereby a binder-free electrode is obtained, and growing an array of vertically aligned carbon nanotubes on the binder-free electrode.

Such an innovation may include other aspects. For example, the method of manufacturing may further include negatively polarizing the binder-free electrode to provide electrons for CrVI reduction and CrIII absorption through electrostatic attraction. In another aspect, the oxide buffer layer is an aluminum oxide. In another aspect, the oxide buffer layer is formed by immersion of the substrate in both (a) a polyacrylic acid solution, and (b) a boehmite (γ-AlOOH) nanoplate suspension. In another aspect, the oxide buffer layer is deposited on the substrate using a wet chemistry method. In another aspect, the substrate comprises a porous stainless steel mesh, the stainless steel mesh comprising a plurality of stainless steel wires, the wires having a curved surface area. In another aspect, the catalyst nanoparticles comprise magnetite (Fe3O4) nanoparticles.

Another innovation includes a method of removing heavy metals from wastewater, the method comprising providing the binder-free electrode with vertically aligned carbon nanotubes, and exposing a wastewater comprising CrVI to the binder-free electrode with vertically aligned carbon nanotubes, whereby CrVI is reducted to CrIII.

Such an innovation may include other aspects. For example, the method of removing heavy metals from wastewater may further comprise negatively polarizing the electrode to provide electrons for CrVI reduction and CrIII absorption through electrostatic attraction. In another aspect, the oxide buffer layer is an aluminum oxide. In another aspect, the oxide buffer layer is formed by immersion of the substrate in both (a) a polyacrylic acid solution, and (b) a boehmite (γ-AlOOH) nanoplate suspension. In another aspect, the substrate comprises a porous stainless steel mesh, the stainless steel mesh comprising a plurality of stainless steel wires, the wires having a curved surface area. In another aspect, the catalyst nanoparticles comprise magnetite (Fe3O4) nanoparticles.

### BRIEF DESCRIPTION OF THE DRAWINGS

FIG. 1 illustrates an increasingly telescopic view of a binder-free carbon nanotube (CNT) electrode, the results of a Raman spectroscopy analysis of the CNTs, and an example of a CNT cut into an arbitrary shape.

FIG. 2 illustrates a scanning electron micrograph of a CNT, and the scanning electron micrographs of the same CNT after put in contact with solid matters.

FIG. 3 illustrates an optical micrograph of a CNT, and the optical micrographs of the same CNT immersed in aqueous solutions.

FIG. 4 illustrates an estimation of electrochemical surface area (ESA) by the cyclic voltammetry of iron cyanide.

FIG. 5 illustrates the specific surface area of CNT arrays of different lengths on CNT electrodes.

FIG. 6 illustrates an electrochemical reduction of Cr^{VI}.

FIG. 7 illustrates a linear sweep voltammograms of CNT electrodes for water reduction.

FIG. 8 illustrates the electrosorption of Cr^{III}.

FIG. 9 illustrates the effects of ESA on Cr^{VI} reduction and Cr^{III} sorption.

FIG. 10 illustrates the recollection of adsorbed Cr^{III} and regeneration of the CNT electrode.

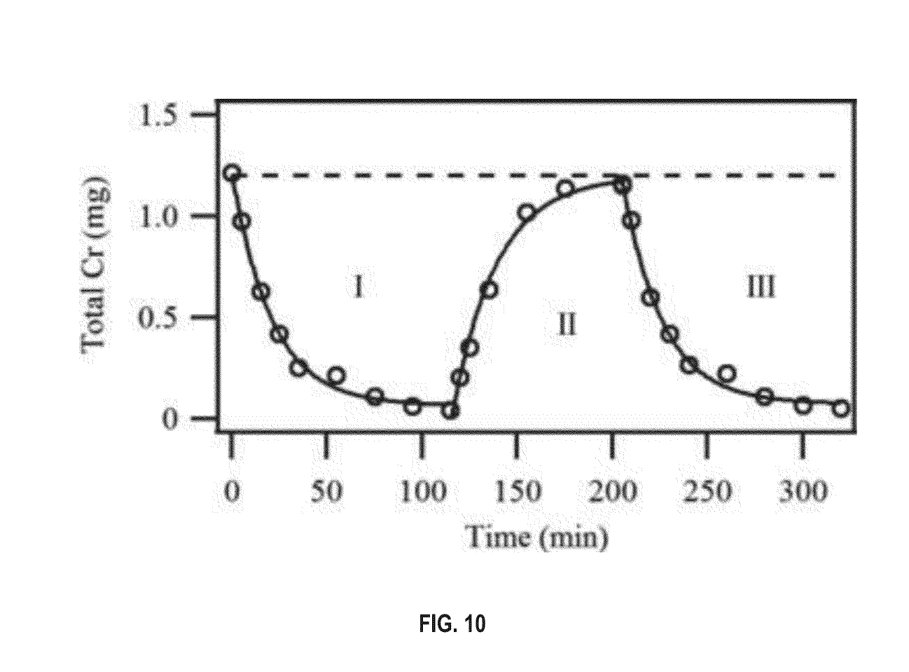

FIG. 11 illustrates increasing ESA by increasing electrode surface roughness in different electrodes.

FIG. 12 illustrates the correlation of a specific electrochemical surface area of CNT electrodes and their CNT mass fraction.

FIG. 13 illustrates an energy dispersive X-ray spectrum of the carbon-paper anode after being used in the electrochemical treatment of chromium.

### DETAILED DESCRIPTION OF THE PREFERRED EMBODIMENT

The following description and examples illustrate a preferred embodiment of the embodiments in detail. Those of skill in the art will recognize that there are numerous variations and modifications of this invention that are encompassed by its scope. Accordingly, the description of a preferred embodiment should not be deemed to limit the scope of the embodiments.

The term “substantially” as used herein is a broad term, and is to be given its ordinary and customary meaning to a person of ordinary skill in the art (and is not to be limited to a special or customized meaning), and refers without limitation to within 30% of the measurement expressed, unless otherwise stated.

The term “wet chemistry” as used herein is a broad term, and is to be given its ordinary and customary meaning to a person of ordinary skill in the art (and is not to be limited to a special or customized meaning), and refers without limitation to use of a liquid phase of a composition or material at a given stage in a process or treatment, and includes (but is not limited to) precipitation, extraction, distillation, immersion, melting point, etc.

The term “heavy metal” as used herein is a broad term, and is to be given its ordinary and customary meaning to a person of ordinary skill in the art (and is not to be limited to a special or customized meaning), and refers without limitation to a metallic chemical element that has a relatively high density. This may include (but is not limited to), mercury (Hg), cadmium (Cd), arsenic (As), chromium (Cr), thallium (Tl), lead (Pb), etc.

The term “oxide” as used herein is a broad term, and is to be given its ordinary and customary meaning to a person of ordinary skill in the art (and is not to be limited to a special or customized meaning), and refers without limitation to a binary compound of oxygen with another element or group.

The term “buffer layer” as used herein is a broad term, and is to be given its ordinary and customary meaning to a person of ordinary skill in the art (and is not to be limited to a special or customized meaning), and refers without limitation to a layer of material that covers or encases a substrate.

The term “catalyst nanoparticle” as used herein is a broad term, and is to be given its ordinary and customary meaning to a person of ordinary skill in the art (and is not to be limited to a special or customized meaning), and refers without limitation to a heterogeneous or a homogeneous catalyst in the form of particles between substantially 1 and 100 nanometers in size.

The term “nanoplate” as used herein is a broad term, and is to be given its ordinary and customary meaning to a person of ordinary skill in the art (and is not to be limited to a special or customized meaning), and refers without limitation to a two-dimensional nanostructure (a structure of intermediate size between microscopic and molecular structures) with a thickness in a scale ranging from substantially 1 to 100 nanometers.

As used herein, the term “vertically-aligned” as used herein is a broad term, and is to be given its ordinary and customary meaning to a person of ordinary skill in the art (and is not to be limited to a special or customized meaning), and refers without limitation to any plurality of CNTs wherein the cylindrical axes of rotation of the individual CNTs are substantially parallel to each other and are substantially perpendicular to a body supporting the individual nanotubes such as, for example, a substrate or a binder layer.

As used herein, the term “nitrogen-doped” as used herein is a broad term, and is to be given its ordinary and customary meaning to a person of ordinary skill in the art (and is not to be limited to a special or customized meaning), and refers without limitation to a carbon nanotube wherein at least a portion of the carbon sites in the graphitic structure of the carbon nanotube are filled with nitrogen atoms instead of with carbon atoms, such that the portion of carbon sites so filled with nitrogen may be detectable by common analytical means known in the art such as, for example, x-ray photoelectric spectroscopy (XPS). Hereinafter these vertically-aligned nitrogen-doped CNTs shall be referred to as VACNTs.

As used herein, the term “relatively” as used herein is a broad term, and is to be given its ordinary and customary meaning to a person of ordinary skill in the art (and is not to be limited to a special or customized meaning), and refers without limitation to 95% of the values of the physical property when measured along an axis of, or within a plane of or within a volume of the structure, as the case may be, will be within plus or minus 20% of a mean value.

All numerical designations, for example, pH, temperature, time, concentration, and molecular weight, including ranges, are approximations which are varied (+) or (−) by increments of 0.1 or 1.0, where appropriate. It is to be understood, although not always explicitly stated that all numerical designations are preceded by the term “about”. It also is to be understood, although not always explicitly stated, that the reagents described herein are merely exemplary and that equivalents of such are known in the art.

As used herein, the term “acidic group” refers to the group which donates a hydrogen ion to the base or which when dissolved in water gives a solution with hydrogen ion activity greater than pure water, namely, a pH less than 7.0. The acidic groups are negatively charged groups at pH higher than 7.0.

As used herein, the term “amide” refers to —CONH₂ group.

As used herein, the term “amine” refers to —NH₂ group.

As used herein, the term “array” refers to a group of CNTs with same attributes as the individual carbon nanotube.

As used herein, the term “basic group” refers to the group which accepts a hydrogen ion or which when dissolved in water gives a solution with pH greater than 7.0. The basic groups are positively charged groups at pH lower than 7.0.

As used herein, the term “carboxylic acid” refers to —COOH group.

As used herein, the term “dendrimer” refers to repeatedly branched molecules. Dendritic molecules are repeatedly branched species that are characterized by their structure perfection. The latter is based on the evaluation of both symmetry and polydispersity. The area of dendritic molecules can roughly be divided into the low-molecular weight and the high-molecular weight species. The first category includes dendrimers and dendrons whereas the second encompasses dendronized polymers, hyperbranched polymers, and brush-polymers (also called bottle-brushes). Dendrimers and dendrons are repeatedly branched, monodisperse, and usually highly symmetric compounds. There is no apparent difference in defining dendrimer and dendron. A dendron usually contains a single chemically addressable group that is called the focal point. Because of the lack of the molar mass distribution high-molar-mass dendrimers and dendrons are macromolecules but not polymers. The properties of dendrimers are dominated by the functional groups on the molecular surface. Dendritic encapsulation of functional molecules allows for the isolation of the active site, a structure that mimics the structure of active sites in biomaterials because dendritic scaffolds separate internal and external functions. For example, a dendrimer can be water-soluble when its end-group is a hydrophilic group, like a carboxyl group.

As used herein, the term “desalted water” refers to water from which salt has been substantially removed.

As used herein, the term “fluid” refers to both gas as well as liquid.

As used herein, the terms “functional,” or “functionalized,” or “functionalization,” refer to any group that imparts selectivity to the CNTs in transporting fluids. The functional groups include, without limitation, charged groups, non-charged groups, or permanent charged groups.

As used herein, the term “liquid” refers to any liquid that has the particles loose and can freely form a distinct surface at the boundaries of its bulk material. Examples of liquid include, but are not limited to, water, industrial streams, chemicals, or bodily liquids. Examples of water include, without limitation, salted water, sea water, well water, underground water, and waste water. Examples of industrial stream include, without limitation, pharmaceutical industry process stream, or food industry process stream. Examples of chemicals include, without limitation, chemicals used in pharmaceutical industry, laboratories, or research organizations. Examples of bodily liquids include, without limitation, diluted, untreated, or treated body fluids such as milk, blood, plasma, urine, amniotic liquid, sweat, saliva, etc.

As used herein, the term “membrane” intends a porous material whose lateral dimension is significantly larger than the dimensions across it.

As used herein the term “nanotube” intends a substantially cylindrical tubular structure of which the most inner diameter size is an average of less than about 6 nm. Nanotubes are typically, but not exclusively, carbon molecules and have novel properties that make them potentially useful in a wide variety of applications in nanotechnology, electronics, optics, and other fields of materials science. They exhibit extraordinary strength and unique electrical properties, and are efficient conductors of heat. The nanotube is a member of the fullerene structural family, which also includes buckyballs. Where buckyballs are spherical in shape, a nanotube is cylindrical, with at least one end typically capped with a hemisphere of the buckyball structure. The name is derived from their size, since the diameter of a nanotube can be on the order of a few nanometers (approximately 50,000 times smaller than the width of a human hair), while they can be up to several millimeters in length. The nanotubes can be single-walled nanotubes (SWNTs), double-walled nanotubes (DWNTs) and multi-walled nanotubes (MWNTs). Nanotubes may be composed primarily or entirely of sp² bonds, similar to those of graphite. This bonding structure, stronger than the sp³ bonds found in diamond, provides the molecules with their unique strength. Nanotubes naturally align themselves into “ropes” held together by Van der Waals forces. Under high pressure, nanotubes can merge together, trading some sp² bonds for sp³ bonds, giving great possibility for producing strong, unlimited-length wires through high-pressure nanotube linking

Nanotubes are comprised of various materials, which include but are not limited to carbon, silicon, silica and selenium. Inorganic nanotubes such as boron nitride have also been synthesized. CNTs include single wall, double wall, and multiwall types. A “single-wall” is one tubular layer, straight or tortuous, of carbon atoms with or without a cap at the ends, while a “double-wall” is two concentric tubular layers, straight or tortuous, of carbon atoms with or without a cap at the ends and a “multi-wall” intends more than two concentric tubular layers, straight or tortuous, of carbon atoms with or without a cap at the ends.

The nanotubes can be arranged in an array wherein a plurality of nanotubes are organized in spatial arrangement with each other. For example, they can be aligned substantially parallel to each other as “substantially vertically aligned” and be generally or substantially perpendicular to a substrate. Nanotubes can be grown off of surfaces that have catalyst particles disposed on the surface in an ordered or disordered array.

As used herein, the term “vertically aligned CNTs” refers to a group of complex hierarchical structures of intertwined tubes arrayed in a nominally vertical alignment due to their perpendicular growth from a substrate. For any plurality of CNTs, the cylindrical axes of rotation of the individual CNTs are substantially parallel to each other and are substantially perpendicular to a body supporting the individual nanotubes such as, for example, a substrate or a binder layer.

As used herein, the term “nitrogen-doped” means that for any given carbon nanotube, at least a portion of the carbon sites in the graphitic structure of the carbon nanotube are filled with nitrogen atoms instead of with carbon atoms, such that the portion of carbon sites so filled with nitrogen may be detectable by common analytical means known in the art such as, for example, x-ray photoelectric spectroscopy (XPS).

As used herein, the term “non-charged group” refers to the group that has no positive or negative charge on it.

As used herein, the term “permanent charged group” refers to the group which has the charge not dependent on the surrounding pH. For example, quartenary ammonium ion has a positive charge.

As used herein, the term “polymer” is a large molecule (macromolecule) composed of repeating structural units typically connected by covalent chemical bonds. Examples of polymer include, but are not limited to, linear and branched polyethylene glycol (PEG), polyamides, polyesters, polyimides and polyurethanes. Examples of polyamides include, but are not limited to, nylon 6; nylon 6,6; and nylon 6,12. Examples of polyesters include, but are not limited to, poly(ethylene terephthalate), poly(trimethylene terephthalate), and poly(trimethylene naphthalate).

As used herein, the term “polyelectrolyte” refers to polymers whose repeating units bear an electrolyte group. These groups will dissociate in aqueous solutions (water), making the polymers charged. Polyelectrolyte properties are thus similar to both electrolytes (salts) and polymers (high molecular weight compounds), and are sometimes called polysalts. Like salts, their solutions are electrically conductive. Like polymers, their solutions are often viscous. Charged molecular chains, commonly present in soft matter systems, play a role in determining structure, stability and the interactions of various molecular assemblies. One of the role of polyelectrolytes is in biology and biochemistry. Many biological molecules are polyelectrolytes. For instance, polypeptides (thus all proteins), and polynucleotides such as DNA, and RNA are polyelectrolytes including both natural and synthetic polyelectrolytes. Other examples of polyelectrolytes include, without limitation, polysterenesulfonate (PSS).

As used herein, the term “salted water” refers to water with salt (Na⁺Cl⁻) in it. The salted water can be sea water. Along with Na⁺ and Cl⁻ ions, the salted water can contain one or more of additional ions. Examples of ions include, but are not limited to, magnesium, sulfur, calcium, potassium, strontium, barium, radium, bromine, etc.

As used herein, the term “transport” refers to separation as well as filtration of the fluid.

In order to more clearly describe the subject matter of the example embodiments, different embodiments of the same subcomponent will be described under a single relevantly-titled subheading. This organization is not intended to limit the manner in which embodiments of different subcomponents may be combined in accordance with the embodiments.

### CNT Modification

In some embodiments, the VACNTs used in the CNTs of the embodiments are pristine CNTs. In other embodiments, the CNTs are functionalized with various functional groups. Non-limiting examples of functional groups include carboxyl groups, carbonyl groups, oxides, alcohol groups, phenol groups, aryl groups, and combinations thereof. In further embodiments, the CNTs of the embodiments may include defective CNTs, such as CNTs with one or more side-wall holes or openings.

In one example embodiment, the electrode may include a transparent substrate. The transparent substrate used in the transparent CNT electrode can be of any type so long as there is a transparent quality, specific examples of which include transparent inorganic substrates, such as glass and quartz substrates, and flexible transparent substrates, such as plastic substrates. Examples of suitable materials for the flexible transparent substrates include polyethylene terephthalate, polyethylene naphthalate, polyether sulfone, polycarbonate, polystyrene, polypropylene, polyester, polyimide, polyetheretherketone, polyetherimide, acrylic resins, olefin-maleimide copolymers, and norbornene resins. These materials can be used either alone or in a combination thereof.

The CNTs used in the CNT composition are not particularly restricted so long as the advantages of the embodiments are not impaired. Specifically, the CNTs can be selected from the group containing single-walled carbon nanotubes (SWCNTs), double-walled carbon nanotubes (DWCNTs), multi-walled carbon nanotubes (MWCNTs), rope CNTs, and combinations thereof. Where SWCNTs are desired for use, metallic CNTs can be selectively separated by a chemical separation process before use.

### Dopants

In various embodiments, the CNTs of the embodiments may also be doped with one or more dopants. Doped CNTs generally refer to CNTs that are associated with one or more dopants. In some embodiments, the dopants are endohedrally included in free spaces within CNTs. In other embodiments, dopants replace carbon atoms within the carbon nanotube structure. In some embodiments, the dopants are exohedrally incorporated between CNTs.

Non-limiting examples of suitable dopants include compounds or heteroatoms containing iodine, silver, chlorine, bromine, potassium, fluorine, gold, copper, aluminum, sodium, iron, boron, antimony, arsenic, silicon, sulfur, and combinations thereof. In some embodiments, the CNTs may be doped with one or more heteroatoms, such as AuCl₃ or BH₃. In some embodiments, the CNTs may be doped with an acid, such as sulfuric acid or nitric acid. In further embodiments, the CNTs of the embodiments may be doped with electrons, holes, and combinations thereof.

In more specific embodiments, the CNTs of the embodiments may be doped with arsenic pentafluoride (AsF₅), antimony pentafluoride (SbF₅), metal chlorides (for example, FeCl₃, CuCl₂, ClLi, KCl, Cd₂Al₂Cl₈, AlCl₄⁻, LiAlCl₄, and/or, NaCl), iodine, melamine, carboranes, aminoboranes, phosphines, aluminum hydroxides, silanes, polysilanes, polysiloxanes, sulfides, thiols, and combinations thereof.

In more specific embodiments, the CNTs of the embodiments may include iodine doped CNTs, such as iodine doped DWCNTs. CNTs with iodine doped DWCNTs have improved electrical properties, including enhanced conductivity, enhanced resistivity, thermal resistance, and improved current carrying capacity.

In further embodiments, the CNTs of the embodiments may be doped with SbF₅. The intercalation of SbF₅ with CNTs can significantly enhance the electrical conductivity of the CNTs, such as by a factor of ten. In some embodiments, the CNTs of the embodiments may be doped with iodine and SbF₅.

Various methods may also be used to dope CNTs with one or more dopants. In some embodiments, the doping occurs by sputtering or spraying one or more doping agents onto CNTs. In some embodiments, the doping can also occur by chemical vapor deposition.

In some embodiments, the doping occurs after the aggregating step that produces the CNTs. In some embodiments, the doping occurs in situ during and/or after the carbon nanotube growing step. In further embodiments, the doping may occur in situ as well as after the formation of the CNTs.

### Polymer Coating

In some embodiments, the CNTs of the embodiments may also be coated with one or more polymers. Non-limiting examples of polymers include polyethylenes, polypropylenes, poly(methyl methacrylate) (PMMA), polyvinyl alcohols (PVA), epoxide resins, and combinations thereof.

Various methods may also be utilized to coat CNTs with polymers. In some embodiments, polymers may be applied to CNTs by spray coating, dip coating, immersion of CNTs into melted polymers, and combinations of such methods. In further embodiments, polymers may be applied to CNTs by evaporation, sputtering, chemical vapor deposition (CVD), inkjet printing, gravure printing, painting, photolithography, electron-beam lithography, soft lithography, stamping, embossing, patterning, spraying and combinations of such methods.

### CNT Arrangements

The CNTs of the embodiments may have various arrangements. In some embodiments, the CNTs may include intertwined threads that are twisted in a parallel configuration with respect to one another. In some embodiments, the CNT threads of the embodiments may be arranged to form cables or wires.

Once the CNTs are formed, various methods may also be used to link the formed CNTs to one another. In some embodiments, the formed CNTs may be linked to one another by twisting individual or multiple CNTs with one another in a parallel configuration. In some embodiments, the linking may include tying the CNTs to one another in a serial configuration.

Various methods may be used to tie or twist CNTs. In some embodiments, a micromanipulator may be used to link the CNTs. In some embodiments, traditional weaving techniques that are used in the textile industry may be used to link the CNTs. In some embodiments, the CNTs may be linked to form cables or wires.

### Substrate

The form of the CNT substrate can vary without limitation in the embodiments presented herein.

In some embodiments the CNT may be grown on a substrate having a two-dimensional plane. The plane may be flat or contain a scored surface. The scored surface may include a pattern of curved semi-circles, sharp saw-tooth patterns, rounded semi-circle patterns, plateaus, ridges, or other modified shapes. The plane may be cylindrical, conical, or semi-spherical with the same surface scored patterns described above. The plane may also be porous and include a pattern of holes. The holes may vary in size and shape, and may be concave inward or downward relative to a side of the plane.

In some embodiments, the CNT may be grown on a substrate having a matrix-type mesh shape. The mesh shape may include a woven pattern with opening portions in the mesh layer. The opening portions may be sized to allow for substantially 400×400 openings per square inch. The substrate can be multi layered or include only one layer. The mesh layer may include rows and columns of ribbons or wires, or both, and may include diagonally running ribbons or wires, or both.

The surface of the substrate may have a defined pattern (for example, a grating) on its surface. For example, the surface may have alternating regions of metal or semiconductor and insulator. The metal or semiconducting embedded materials may be partially or totally capped off by a sacrificial layer which can be removed later to provide a suspended nanotube nanoribbon structure.

In one example embodiment, the CNTs may be grown on a fibrous substrate. The substrate may comprise fibers which act to maintain the dispersion (or exfoliation) of the CNTs during processing, and/or which may add mechanical integrity to the final product. Such fibers can be sacrificial (removed from the structure during further processing, such as by chemical or heat treatments) or can remain an integral part of the finished device.

The fibers that may be used in the composition disclosed herein may be mineral or organic fibers of synthetic or natural origin. They may be short or long, individual or organized, for example, braided, and hollow or solid. They may have any shape, and may, for example, have a circular or polygonal (square, hexagonal or octagonal), include surfaces with a plurality of half spherical curvature cross sections, depending on the intended specific application.

The fibers can be those used in the manufacture of textiles as derived from bio-mineralization or bio-polymerization, such as silk fiber, cotton fiber, wool fiber, flax fiber, feather fibers, cellulose fiber extracted, for example, from wood, legumes or algae. Depending on the fluids to be separated, medical fibers may also be used in the present disclosure. For instance, the resorbable synthetic fibers may include: those prepared from glycolic acid and caprolactone; resorbable synthetic fibers of the type which can be a copolymer of lactic acid and of glycolic acid; and polyterephthalic ester fibers. Nonresorbable fibers such as stainless steel threads may be used.

The fibers may be chosen from:

(a) at least one polymeric material chosen from single or multi-component polymers such as nylon, acrylic, methacrylic, epoxy, silicone rubbers, synthetic rubbers, polypropylene, polyethylene, polyurethane, polystyrene, polycarbonates, aramids (i.e., Kevlar® and Nomex®), polychloroprene, polybutylene terephthalate, poly-paraphylene terephtalamide, poly(p-phenylene terephtalamide), and polyester ester ketone, polyesters [for example, poly(ethylene terephthalate), such as Dacron®], polytetrafluoroethylene (i.e., Teflon®), polyvinylchloride, polyvinyl acetate, viton fluoroelastomer, polymethyl methacrylate (i.e., Plexiglass®), and polyacrylonitrile (i.e., Orion®), and combinations thereof;

(b) at least one ceramic material chosen from boron carbide, boron nitride, spinel, garnet, lanthanum fluoride, calcium fluoride, silicon carbide, carbon and its allotropes, silicon oxide, glass, quartz, silicon nitride, alumina, aluminum nitride, aluminum hydroxide, hafnium boride, thorium oxide, cordierite, mullite, ferrite, sapphire, steatite, titanium carbide, titanium nitride, titanium boride, zirconium carbide, zirconium boride, zirconium nitride, and combinations thereof;

(c) at least one metallic material chosen from aluminum, boron, copper, cobalt, gold, platinum, palladium, silicon, steel, titanium, rhodium, iridium, indium, iron, gallium, germanium, tin, tungsten, niobium, magnesium, manganese, molybdenum, nickel, silver, zirconium, yttrium, their oxides, hydrides, hydroxides and alloys thereof; and

(d) at least one biological material or derivative thereof chosen from cotton, cellulose, wool, silk, and feathers, and combinations thereof.

In addition to the foregoing list of fibrous substrate material, the material made according to the present disclosure may comprise at least one non-fibrous substrate material, such as particles or beads made of the same materials previous described.

The liquid mixture that the devices of the emobidments can be used to separate may have a non-zero interfacial tension or different densities or both. The separation of those liquids that do not separate due to density difference are expected to be separated using a final separating element which may or may not contain CNTs.

The liquids in question can be chosen from water, oils, fuels, organic solvents or combinations thereof.

The fuels can be chosen from gasoline, kerosene, aviation fuel, diesel, ultralow sulfur diesel, biodiesel or combinations thereof. Aviation fuel includes but is not limited to an unleaded paraffin oil or a naphtha-kerosene blend. In one embodiment, aviation fuel includes JP-8 (“Jet Propellant 8”).

The organic solvents can be chosen from hexane, benzene, toluene, chloroform or combinations thereof.

### Carbon Nanotube Catalyst

Generally, the hollow geometry of CNTs leads to large specific surface areas which allows CNTs support for heterogeneous catalysts. CNTs further include a relatively high oxidation stability which can be induced by their structural integrity and chemical inertness. Additionally, CNTs have physical properties that include electrical conductivity, mechanical strength, and thermal conductivity, which are valued factors for catalyst supports.

### Fuel Cell Cathodes

Among various non-noble-metal catalysts for the oxygen-reduction reaction (ORR), CNTs formed by high-temperature treatment of ferrocene, for example, have been demonstrated to show promising catalytic activity. This activity has been theorized to be attributed to active sites of FeN₂—C and/or FeN₄—C within the nanotubes. At such active sites, iron (Fe) may be coordinated with two or four nitrogen (N) atoms arranged in a pyridinic or a pyrrolic structure.

On the other hand, CNTs produced by pyrolysis of iron(II) phthalocyanine (FePc, a metal heterocycle molecule containing nitrogen) can be used as effective ORR electrocatalysts even after a complete removal of the residual Fe catalyst. The pyrolysis may be carried out either in the presence of and or in the absence of ammonia (NH₃) vapor. Moreover, the VACNTs are nitrogen-doped.

The VACNTs catalyze a four-electron ORR process in alkaline electrolytes with a much higher electrocatalytic activity, a lower overpotential (i.e., the difference between thermodynamic and formal potentials), a smaller crossover effect (i.e., decrease in activity as a result of species produced at the anode crossing over to the cathode), and an increased long-term operational stability when compared with commercially available or similar platinum electrodes. Without intent to be limited by theory, the ORR at the VACNT electrode may take place through reduction of the positively-charged carbon (C) atoms in the nanotubes around the electron-accepting N atoms by the action of the electrochemical cycling and reoxidation of these reduced C atoms to their oxidized state by adsorbed oxygen (O₂) molecules. Thus, the high surface area, good electrical and mechanical properties, and superb thermal stability intrinsically characteristic of CNTs can provide additional advantages for the nanotube electrode to be used in fuel cells under both ambient and harsh conditions (for example, at elevated temperatures where other metal-free electrodes, such as polymers, fail due to thermal degradation).

The fuel cell cathode may comprise a supported nanotube array attached to a contact portion of a cathode body. As may be suitable for the desired application, the supported nanotube array may be attached to a contact portion covering any amount of the cathode body. As illustrative examples not shown, the supported nanotube array may cover only a tip of a cylindrical cathode body, a surface feature of a flat cathode body such as a plate, or any amount up to a substantial entirety of a cathode body of any desired shape.

The supported nanotube array may comprise a binder layer, attached to the outer surface of the cathode body, and a catalytic layer supported by the binder layer. The catalytic layer may comprises a plurality of VACNTs.

The binder layer may be electrically conductive and thus electrically couples the catalytic layer to the cathode body. For example, the catalytic layer can be electrically coupled to the cathode body through a contact portion within the cathode body. Therefore, the binder layer may comprise any electrically conductive material suitable for supporting the VACNT array of the catalytic layer to the cathode body. In one embodiment, the binder layer may comprise a conductive polymer such as, for example, a polystyrene. In this sense, the term “polystyrene” is not intended to be limited to any one type of composition and may include homopolymers and copolyments of styrene. Thus, “polystyrene” refers to any polymer containing styrene repeating units, without regard to molecular size, stereochemistry, or the presence of additional polymer units.

The binder layer may further comprise non-aligned CNTs that form a composite with a conductive polymer. In an example embodiment, the binder layer may comprise a composite of a polystyrene and nonaligned CNTs. The nonaligned CNTs may comprise a graphitic structure containing carbon atoms, or the nonaligned CNTs may be doped. In an example embodiment, at least a portion of the nonaligned CNTs are nitrogen-doped. Without intent to be limited by theory, the presence of nonaligned CNTs within a conductive polymer nanotube composite can stabilize the catalytic layer and strengthen the bonding between the binder layer and the catalytic layer, such as through van der Waals interactions.

One example embodiment of a method for fabricating a fuel cell cathode may include first providing a substrate containing an array of vertically-aligned nitrogen-doped CNTs bound to a surface of the substrate. Such a substrate may be provided wherein a catalytic layer containing an array of VACNTs can be deposited on a substrate. The substrate may comprise any material suited for growth of CNTs thereon. In specific examples, the substrate may comprise a silica (SiO₂) substrate, such as a quartz plate, or a silicon wafer with a native or prepared layer of SiO₂ thereon.

The array of VACNTs may be deposited by pyrolyzing a hydrocarbon or a metalorganic compound in the presence of the substrate. In example embodiments, the metalorganic compound may be a sandwich compound such as, for example, ferrocene, or nitrogen-containing metal heterocycle such as, for example, an iron(II) phthalocyanine (FePc). The FePc may be substituted with one or more functional groups and may be pyrolyzed, for example, at approximately 800-1100° C. in a quartz tube furnace or other suitable vessel. When a nitrogen-containing heterocycle is pyrolyzed, a concurrent integration of nitrogen into the graphitic structure or the plurality of nanotubes occurs during the pyrolysis. Otherwise, nitrogen can be incorporated into the nanotubes, for example, by exposing the nanotubes to a nitrogen source such as ammonia gas (NH₃) during or after the pyrolysis. Thus, the pyrolyzing optionally can be performed in the presence of NH₃ gas, even when a nitrogen-containing heterocycle is pyrolyzed, and may provide a higher level of nitrogen doping to the CNTs. In one specific example, the pyrolysis may be carried out in a gas flow containing approximately 48 vol. % Ar, approximately 28 vol. % H2, and approximately 24 vol. % NH₃. Residual metal particles derived from the metalorganic compound optionally may be removed, such as by electrochemical oxidation. Without intent to be limited by theory, removal of residual metal particles may improve the electrochemical characteristics of the fuel cell cathode fabricated according to the above method.

The binder layer can be coated onto the top surface of the catalytic layer. The binder layer may include a composite of a conductive polymer, such as polystyrene, and nonaligned carbon nanotubes (NA-NCNTs). The binder layer can be coated onto the catalytic layer, for example, from a toluene solution containing about 10 wt % polystyrene and about 2.0 mg/mL CNTs. The resulting structure may be heated up to about 140° C. for about 1 minute in air to cause a controlled infiltration of the binder layer into the VACNT array that makes up the catalytic layer. The heating effectively melts the composite material sufficiently to bind the free ends of the CNTs of the catalytic layer into the binder layer.

The binder layer may be etched to produce exposed nonaligned nanotubes on the etched surface of the binder layer. In one example, water-plasma etching can be used to etch the binder layer. The substrate may be removed to result in a supported nanotube array, wherein the supported nanotube array is a free-standing structure having exposed nonaligned nanotubes on one side. The substrate can be removed, for example, by immersing at least the substrate in an aqueous HF solution (for example, 1:6 v/v).

In example embodiments, the individual VACNTs of the catalytic layer may be about 5 μm to about 15 μm long and may have outer diameters of approximately 20 nm to approximately 30 nm. In one example embodiment, the VACNTs of the catalytic layer may be about 8 μm long and may have outer diameters of approximately 25 nm. The width of the catalytic layer, controlled by the length of the individual VACNTs prepared according to the embodiments disclosed above, can be limited by the size of the furnace or other vessel used to grown the VACNTs. It will be appreciated, therefore, that the nanotube dimensions described above are not intended to limit the catalytic layer to any particular dimension, because the furnace or vessel used to grow the VACNTs can be scaled up as desired to produce a catalytic layer that can be considerably thicker or covers a much larger portion of the outer surface of the cathode body.

Example catalytic layers prepared as described above were analytically characterized. In general, the individual VACNTs of the catalytic layers were found to exhibit a zigzag-like path along their length, thus slightly altering the individual VACNTs from a straight cylindrical geometry. Without intent to be limited by theory, the zigzag-like path can be attributable to the integration of nitrogen into the graphitic structure of the nanotubes. The presence of structural nitrogen was confirmed by x-ray photoelectron spectroscopy (XPS). The aligned structure remained largely unchanged after the electrochemical purification, but some evidence of bundling was observed.

The binder layer may further comprise NA-NCNT that form a composite with a conductive polymer. In an example embodiment, the binder layer may comprise an electrically conductive composite of a polystyrene and nonaligned CNTs. The nonaligned CNTs may comprise a graphitic structure containing carbon atoms, or the nonaligned CNTs may be doped. In an example embodiment, at least a portion of the nonaligned CNTs are nitrogen-doped.

In summary, a new class of metal-free fuel cell cathodes for ORR and fuel cells have been described. The cathodes comprise a catalytic layer of vertically-aligned nitrogen-doped CNTs. The ORR on the cathodes proceeds via a four-electron pathway in alkaline fuel cells. The VACNT cathodes showed ORR performance superior to that of commercially available platinum electrodes with respect to electrocatalytic activity, long-term operation stability, and tolerance to crossover effects. Without intent to be limited by theory, the incorporation of electron-accepting nitrogen atoms in the conjugated nanotube carbon plane facilitates the ORR on the NCNT electrodes during electrochemical cycling, as absorbed O₂ molecules reduce the charge-deficient carbon atoms around the electron-rich nitrogen atoms and then reoxidize the reduced carbon atoms to their oxidized states. It may be appreciated that nitrogen doping as described herein may be applied to the design and development of various other metal-free efficient ORR catalysts for fuel cells and other applications.

### Carbon Nanotube Electrode

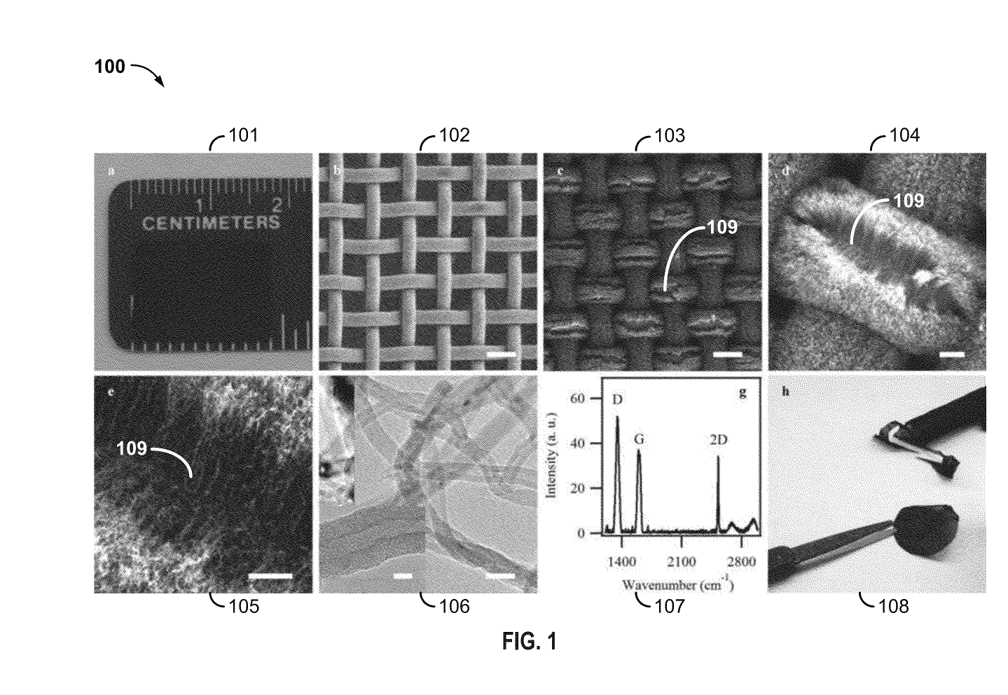

A binder-free CNT electrode may be prepared by growing VACNTs directly on SSM after activation using chemical vapor deposition (CVD). A typical CNT electrode is shown in varying levels of magnification in FIG. 1. In one example embodiment, the electrode resembles a piece of dark cloth 101. The electrode may be prepared using a piece of 304 SSM with a 400×400 openings per square inch (wire diameter, 25 μm; opening size, 38×38 μm) as support for VACNTs (see, 102). In other embodiments, the electrode may include a substrate of a solid, substantially planar surface with ripples or ridged surface, or may include any pattern of woven material. Scanning electron microscopy (SEM) shows that SSM openings are closed up by VACNTs grown vertically on stainless steel wires (see, 103). The CNT arrays show cracks 109 in the direction of gas flow, presumably formed under stress. Through the cracks 109, the vertical alignment of individual CNTs is visible (see, 104 and 105). Transmission electron microscopy (TEM) shows that individual CNTs have a diameter of ca. 30 nm with ca. 30 walls (see, 106). Raman spectroscopy confirms that CNTs are of good quality with a D/G ratio of 1.3 (size of in-plane graphene crystallites: 6.4 nm; (see, 107). Between individual CNTs, there are channels of tens of nanometers in diameters that can facilitate mass transfer in and out of CNT arrays. Because stainless steel wires are thin, the CNT electrode can be readily cut into any arbitrary shape using a pair of scissors, providing flexibility to device designs (see, 108).

To synthesize VACNT arrays using CVD, a buffer layer of an oxide may be used to separate the supporting substrates and catalyst nanoparticles. In one example embodiment, a buffer of layer of aluminum oxide (Al₂O₃) may be used to separate the supporting substrate and catalyst nanoparticles. The aluminum oxide buffer may suppress the diffusion and aggregation of catalyst nanoparticles, and promote the aromatization of carbon atoms during CNT growth. The buffer may be deposited on the substrate before catalyst deposition using physical techniques such as e-beam evaporation and thermal sputtering. Buffer layers deposited using low-cost wet chemistry-based methods such as drop casting, spin coating, dip coating, and layer-by-layer (LBL) assembly have only produced VACNT arrays with length up to several hundred micrometers. To develop large-scale applications of VACNTs, a wet chemistry method of buffer deposition may be required. In one example embodiment, this method may involve four steps, including (1) immersion of a substrate material in polyethyleneimine (PEI) solution, (2) immersion of the substrate material in polyacrylic acid (PAA) solution, (3) immersion of the substrate material in boehmite suspension, and (4) annealing the substrate material at 750° C. In one example the substrate material may be a SSM, but as noted above, the material may include a range of metallic or non-metallic materials. Suitable metal can be a metal such as ferrous and nonferrous metals and precious metals. Suitable ferrous metals are iron, cobalt, and nickel alloys and steels, including high speed steel. Non-ferrous metals are listed aluminum, magnesium, copper, zinc, lead, gold, tin, silver, mercury, and titanium, and alloys thereof. Other examples of the metal may be vanadium, chromium, manganese, tantalum or tungsten, and alloys thereof or alloys brass and bronze. May also be used are rhodium, palladium, and molybdenum. The metal may be pure, or in admixture with each other. Preferably aluminum and its alloys. In addition to pure, still preferably aluminum. The metal can be in granular or particulate or powder form and can be used in accordance with the method of the embodiments. The thickness of the buffer layer can be controlled by repeating LBL assembly (steps 2 and 3) before performing annealing (step 4).

A primary component of this example can be the use of a boehmite (γ-AlOOH) nanoplate as a catalyst nanoparticle. The buffer of the substrate material may be subject to deposits of boehmite nanoplates using a layer-by-layer (LBL) assembly. The boehmite nanoplates may be synthesized by hydrothermal transformation of aluminum isopropoxide. The nanoplates may be drop-cased on the substrate material and annealed at 750° C. for substantially 30 min to mimic the annealing step in the actual buffer preparation. For growing VACNT arrays, boehmite nanoplates may be deposited on the substrate material using LBL assembly and then transformed from boehmite to γ-Al₂O₃ by annealing. A linear regression gave an estimate of the thickness per assembly cycle to be 19(±3) nm or approximately three times the thickness of the boehmite nanoplates.

To increase length of the VACNTs, magnetite (Fe₃O₄) nanoparticles may be deposited on the γ-Al₂O₃ buffer layer. The substrate material may be annealed again at substantially 750° C. to remove any remaining organic molecules from LBL assembly. In one example embodiment, VACNT arrays may be grown in quartz tubing using ethylene as a carbon source, and a mixture of hydrogen an argon (substantially 1:1) as carrier gases.

In summary, the synthesis of substantially millimeter-long VACNT arrays are made possible by creating γ-Al₂O₃ buffer on a substrate material using LBL assembly of boehmite nanoplates and annealing. The length of VACNT arrays was shown to be insensitive to buffer thickness, which may simplify the quality control of buffer deposition. In comparison, buffer thickness often needs to be painstakingly controlled when physical methods such as e-beam evaporation and thermal sputtering are used. Furthermore, the LBL assembly of premade boehmite nanoplates may be a wet chemistry-based method that can be relatively easy to be scaled up.

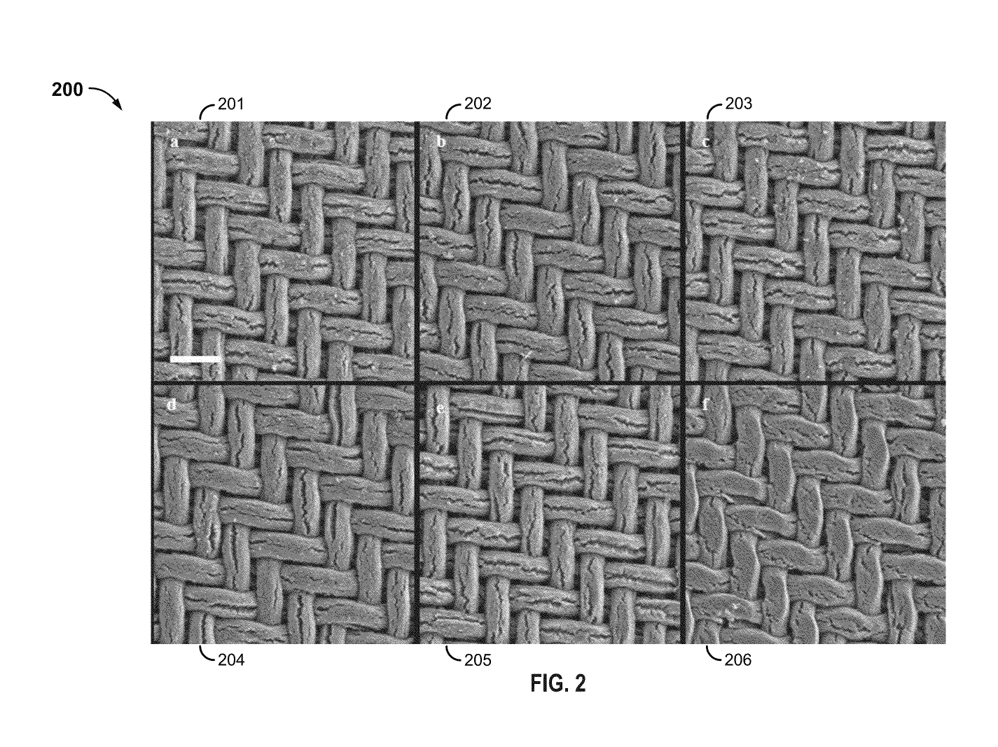

FIG. 2 includes six electron micrographs illustrating that the CNT electrode may maintain excellent structural integrity after being put in contact with solid matters 200. For example, FIG. 2 includes scanned electron micrographs of a pristine carbon nanotube (CNT) electrode 201 and the same electrode after being dropped face-down to ground from 0.5 m 202, 1 m 203, 2 m 204, 3 m 205, and 4 m 206. CNTs in contact with ground are increasingly pressed as the dropping height and the intensity of impact increase. However, there may be no discernible change of the structure of CNT arrays or evidence of broken CNTs. Scale bar: 100 μm.

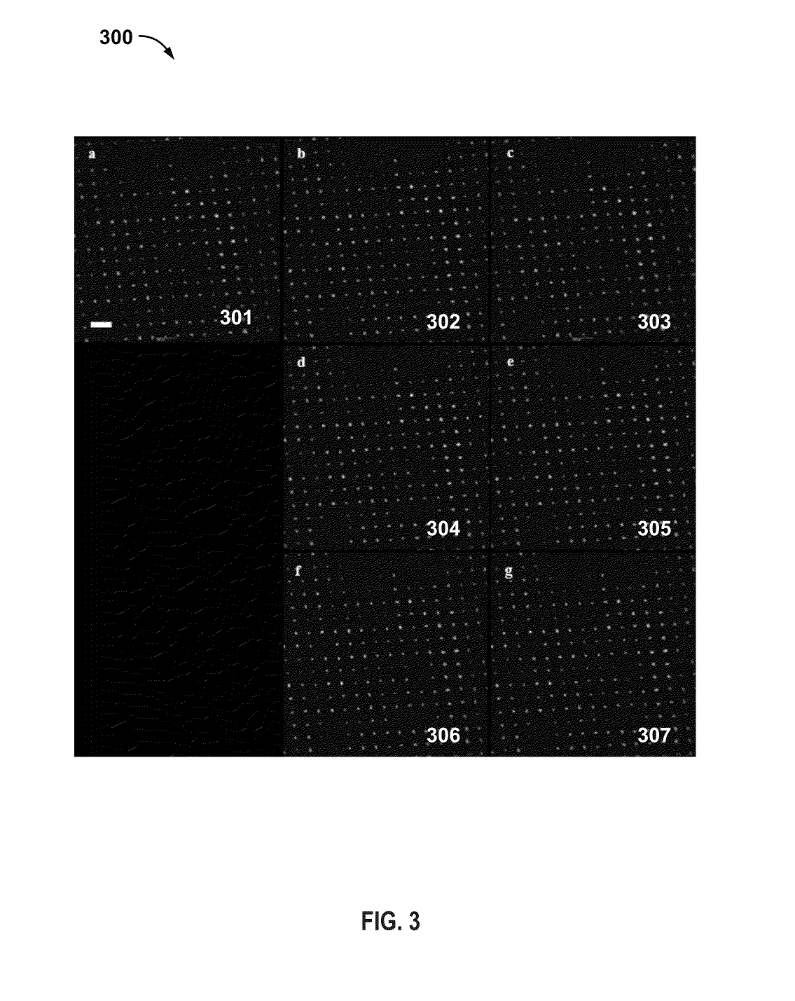

FIG. 3 includes seven optical micrographs of a carbon nanotube (CNT) electrode 300, six of which are immersed in a pH solution, showing that the CNT electrode may maintain structural integrity after being immersed in aqueous solutions. For example, 301 illustrates an optical micrograph of a CNT electrode. 302 illustrates the same CNT electrode 300 immersed in a pH 7 solution for 10 min, and 120 min 303, the same electrode after the solution pH has been adjusted from 7 to 4 for 10 min 304 and 120 min 305, and the same electrode after the solution pH has been adjusted from 4 to 0 for 10 min 306 and 120 min 307. The bright spots in the micrographs are light passing through the remaining openings that are not blocked by CNT arrays (cf. FIG. 1c in the main text). Potential swelling or stripping of CNTs from the electrode may have resulted in the expansion of the openings, which may not be observed in this series of micrographs. Instead, the total area of the bright spots accounts for a constant 3.3% of the total micrographic area throughout the experiments, confirming that there can be no swelling or stripping of CNT arrays in solutions having pH from 0 to 7. Scale bar: 100 μm.

Using high-resolution TEM observations (see, for example, 106), no metal particles were observed inside the CNT nanotubes directly grown on SSM. This can be different from CNTs prepared by catalyst particles dispersed on powder supports. Because the dispersed catalysts do not have high affinity with the supports and thus are mobile at the elevated temperature of CVD, CNTs prepared using powder supports often contain 4-50% (by weight) residual catalysts as particles inside the nanotubes. To eliminate the influence of residual catalysts on the CNTs’ reactivity, aggressive treatment with boiling concentrated nitric acid may often be required to open up the nanotubes in order to remove the residual catalytic nanoparticles. The absence of catalyst nanoparticles inside CNTs directly grown on SSM suggests that the unique synthesis technique disclosed herein has greatly reduced catalyst mobility and thus prevented the contamination of CNTs by residual catalytic nanoparticles. As a result, it was not necessary to treat the CNT electrodes for residual catalytic nanoparticles before use.

### Electrochemical Surface Area of the CNT Electrode

The arrangement of CNT arrays on SSM represents a 3-D hierarchical structure. This structure has a surface area much greater than that of a metal-sheet electrode with the same macroscopic size. However, not all the surfaces of individual CNTs can participate in electrochemical reactions and the portion that does gives ESA. To facilitate understanding of the embodiments, three terms related to the surface area of an electrode are defined herein. First, the geometric surface area (GSA) can be defined as half of a surface area of a two-dimension plate. Second, the specific overall surface area (sOSA) can be defined as the ratio of the total surface area of a CNT electrode to the GSA of the SSM supporting it. Third, the specific electrochemical surface area (sESA) can be defined as the ratio of ESA to GSA.

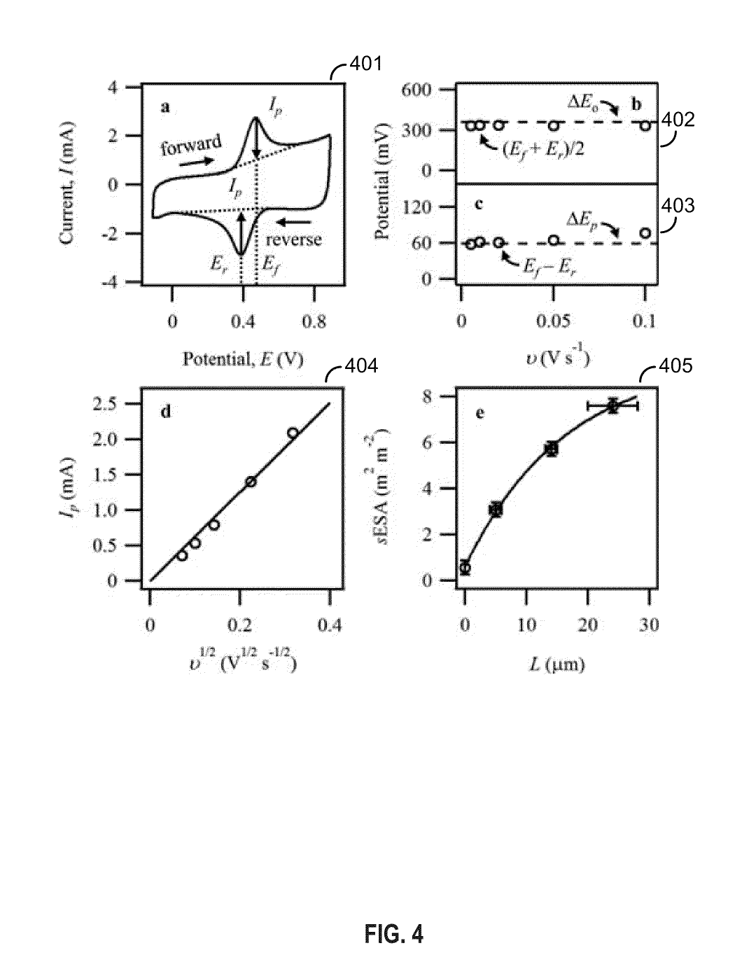

FIG. 4 provides estimations of ESA by the cyclic voltammetry of iron cyanide. Graph 401 illustrates a typical voltammogram (scan rate: υ=100 mV s⁻¹). Graph 402 provides a comparison of (E_{f}+Eᵣ)/2 with the standard potential E₀ of ferricyanide reduction (dashed line: 370 mV). Graph 403 illustrates a comparison of E_{f}−Eᵣ with the theoretical value of ΔEₚ=59 mV (dashed line). Graph 404 provides a linear correlation between Iₚ and υ^{1/2}. Graph 405 illustrates an increase of specific ESA with CNT length L: sESA=15.1(±0.7)−14.1(±0.7) exp[−0.063(±0.005)L] (R²=0.999). Solution: 5 mM potassium ferricyanide and 0.1 M potassium nitrate. Electrode: a−d, L=14(±1) μm. The ESA of the CNT electrode was measured by cyclic voltammetry in an aqueous solution containing 5 mM K₃Fe(CN)₆ as the redox probe and 0.1 M KNO₃ as the background electrolyte. As shown in 401, the voltammogram has two distinctive Faradaic peaks over the capacitive background, produced by the reversible reduction of ferricyanide to ferrocyanide:

[Fe^{III}(CN)₆]³⁻+e⁻ [symbol] [Fe^{II}(CN)₆]⁴⁻ (2)

According to the Nernst equation, the summation of the peak potentials can equal to twice the standard potential of reaction 2 (E₀=370 mV):

(E_{f}+Eᵣ)/2=E₀ (3)

Whereas their difference may have a value of ΔEₚ=59 mV at 25° C.:

E_{f}−Eᵣ=ΔEₚ (4)

As shown in 402 and 403, (E_{f}+Eᵣ)/2=426(±3) mV and E_{f}−Eᵣ=65(±7) mV, which satisfy equations 3 and 4 after considering over-potential (due to concentration difference between the bulk solution and the electrode surface as well as resistance to diffusion through the electrical double layer near the electrode surface), indicating that the measurement system can be configured properly. ESA can be estimated from the mass-transfer controlled behavior of reaction 2 using the Randles-\check{S}ev\check{c}ik equation:

I_{P}=268600n^{3/2} ESAD^{1/2} C_{T}υ^{1/2} (5)

Where I_{P} is the peak current (averaged from forward and reverse scans), n=1 is the number of electrons transferred in the ferric-to-ferrous reduction, D=6.7×10⁻⁶ cm² s⁻¹ is the diffusion coefficient, C_{T}=5×10⁻⁶ mol cm⁻³ is the total concentration of iron cyanide, and υ is the scan rate. As shown in 404, linear regression of I_{P} and υ^{1/2} gives ESA=1.14(±0.06) cm² (R²=0.99).

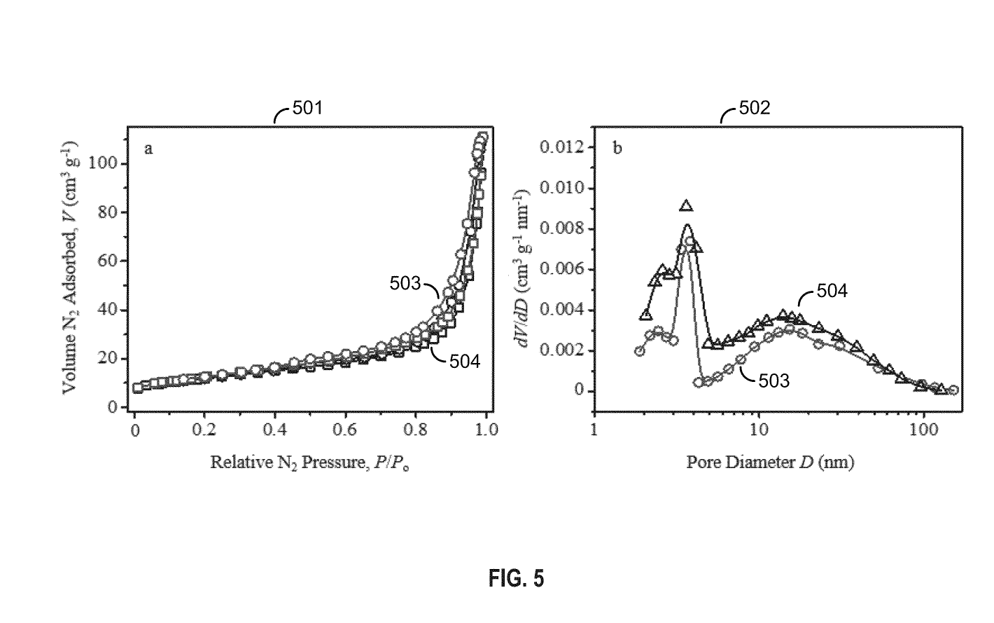

According to ESA=sESA×GSA and GSA=0.2 cm², sESA=5.7(±0.3) m² m⁻², which may be approximately 8% of the corresponding sOSA of 68(±0.3) m² m⁻². To estimate sOSA, the total surface area of the electrode was measured using the Brunauer-Emmett-Teller (BET) adsorption of nitrogen, which gave a specific surface area of 0.38 m² g⁻¹ (36.6 m² g⁻¹ excluding the mass of SSM or 13.8 cm² for the electrode with GSA=0.2 cm² and a mass of 3.6 mg). For example, FIG. 5 illustrates the specific surface area of CNT arrays on CNT electrodes. Graph 501 illustrates the isotherm of nitrogen (N₂) at 77 K. The isotherms are classified as type IV isotherms containing mesopores. The overlapping of the isotherms obtained with different CNTs suggest that specific surface area can be independent of CNT length. Graph 502 illustrates pore size distribution calculated by the non-local density functional theory. The pore size distribution plot of the CNTs exhibits a wide pore size distribution ranging from 2 nm to 100 nm, which can be common for CNT samples. The pore size below and above 10 nm can be attributed to the inner cavity of CNTs and the porous structure formed between CNTs, respectively. CNTs with different lengths are distinguished: 503, 5(±1) μm; 504, 24(±4) μm. Electrodes with different CNT lengths were prepared by shortening or extending the CVD synthesis time. As the VACNT length L increases from 0 to 24 μm, sESA increases exponentially from 0.57(±0.31) m² m⁻² (bare SSM) to 7.6(±0.3) m² m⁻², as shown in 405. This represents a 13× improvement of sESA by VACNT growth.

Control over the Diameter, Length, and Structure of the Carbon Nanotube

CNTs can be applied in diverse technologies, ranging from medical imaging to transparent and conductive coatings; in nearly every instance, the material performance depends on the uniformity and tunability of nanotube diameter as well as wall number (for example, single-walled versus multiwalled). One strategy for controlling these essential material features may be to manipulate the metal catalysts used in CNT production. In one example, these catalysts may be aerosols of reactive iron particles; a carbon feedstock such as ethylene when exposed to these metals decomposed above 800° C., yielding carbon that solubilized in the metals. CNT growth, it was believed, initiated when carbon concentrations became high enough to start the formation of graphitic shells at the metal particle surface. Kukovitsky et al. showed that reduction in the size of the metal catalysts led to smaller diameter CNTs, and the findings suggested that the breadth of the particle dictated the tube diameter; later work illustrated how the composition of the catalyst, particularly with the introduction of molybdenum, may change the helicity and number of tube walls (Kukovitsky et al., Correlation between metal catalyst particle size and carbon nanotube growth. Chemical Physics Letters 2002, 355 (5-6), 497-503).

Iron catalysts formed in the gas phase have been supported on substrates such as alumina, and CNT growth occurs from the surface forming thick and dense films. The VACNT carpets are particularly ideal for applications including separation membranes, supercapacitors, and field-emitters. Yamada et al. demonstrated that when catalysts deposited through gas-phase processes were smaller it was possible to make very small diameter (for example, 2 nm) CNTs (Yamada et al., Nat. Nanotechnol. 2006, 1, 131-136). Whether the diameter of the catalyst defined tube diameter over all catalyst sizes remains an open question for catalysts deposited via the gas phase. Whereas this process yields catalysts with diameters well under 3 nm, the materials can ripen on the surface at high metal coverages and finally increase the catalyst size distributions. More systematic studies that examine fully how catalyst structure can dictate CNT structure require alternate approaches to catalyst formation.

One strategy may be to form iron oxide nanoparticles as catalyst precursors through chemical means, evaporate them onto substrates, and then reduce them to metals in the growth chambers prior to CNT growth. During the last process, the organic coatings present on the particles are volatilized and the catalyst shrinks in size and converts to zero valent iron particles. Hafner et al. was the first to demonstrate the feasibility of this approach by applying broadly distributed Fe—Mo nanoparticles to the growth of double-walled CNTs (Hainer et al., Chem. Phys. Lett. 1998, 296, 195-202). Nishino et al. reported that 3.2 nm diameter colloidal Fe—Mo nanocrystals may be used to grow high-quality single-walled CNT carpets (Nishino et al., Phys. Chem. C 2007, 111, 17961-17965). Iron oxide nanocrystals from 4.5 to 16 nm in diameter also were applied to the growth of primarily multi-walled nanotube films.

It has been demonstrated that organically modified iron oxide nanocrystals may serve as catalysts for CNT growth despite their surface coating and oxidized state. Existing research has underlined the importance of the growth substrate to CNT growth; alumina, for example, outperforms TiO₂, SiO₂, and ZrO₂ in forming uniform and dense CNT films presumably because the strong interactions between metallic iron and alumina limit ripening of the catalyst particles at high temperatures. The addition of aluminum into a precursor catalyst such as iron oxide, forming aluminum ferrite, may mimic or even augment this effect, resulting in less catalyst ripening and narrower CNT diameter distributions. Additionally, by replacing some iron with aluminum, the catalyst particles may contain less iron available for CNT growth. This may lead to the production of CNT with smaller diameters as compared with similar sized pure iron oxide catalysts.

Herein, it is disclosed how both aluminum ferrite and iron oxide nanocrystals can be applied as catalysts for CNT growth in a water-assisted chemical vapor deposition (CVD) process. These particles (d from 4 to 40 nm) were highly uniform in diameter (σ<10%); this feature allowed for a systematic examination of how catalyst composition and size affected CNT structure. The evaporation of nanocrystal solutions onto alumina yielded submonolayer coverage of particles; at temperatures above 750° C., exposure of these substrates to both acetylene and water resulted in the production of CNTs. The outer diameter of the CNTs increased as the particle diameter increased; additionally, larger catalyst particles yielded CNTs with increasing numbers of walls. However, the smallest aluminum ferrite catalysts coupled to limited acetylene delivery resulted in films with >60% single-walled CNT content. Whereas many features of the CNT growth were similar between the aluminum ferrite and the iron oxide nanocrystals, two differences were apparent. First, CNT growth rates were 10 times faster for the ferrites than for pure iron oxides, and as a result thicker films may be formed by starting with aluminum ferrites. Also, the quality of the CNTs, as measured by Raman spectroscopy, was substantially improved when aluminum ferrite was used as a catalyst.

### Chemicals

Iron oxide, hydrated [FeO(OH), catalyst grade, 30-50 mesh], aluminum hydroxide (Al(OH)₃, reagent grade), oleic acid (technical grade, 90%), and 1-octadecene (ODE, technical grade, 90%) may be used. All nanocrystals were synthesized under nitrogen. For the CNT carpet growth, ultra-high-purity ethyne (C2H2, acetylene) and molecular hydrogen (H2) gases were purchased from Matheson Tri-Gas.

### Iron Oxide Nanocrystals

Monodisperse iron oxide nanocrystals with a wide size range from 4 to 40 nm may be synthesized based on Yu, W. W., et al. Chem. Commun. 2004, 2306-2307. The purified iron oxide nanocrystals can be purified using methanol and precipitated by adding acetone. The cleaned colloidal nanocrystals may be redispersed in hexane.

### Synthesis of Aluminum Iron Oxide Nanocrystals

4 nm aluminum iron oxide may be obtained by using 0.045 mmol iron oleate, 0.019 mmol aluminum oleate, and 2 mmol oleic acid in 5 g ODE at 320° C. for 2 h. 10 nm aluminum iron oxide may be prepared by 0.7 mmol FeO(OH) and 0.3 mmol Al(OH)3 with 3 mmol oleic acid in 5 g ODE at 320° C. for 1 h. For 15 nm aluminum iron oxide, 10 nm nanocrystal preparation conditions may be used, except for using 4 mmol oleic acid. The iron oxide and aluminum iron oxide nanocrystals can be purified using methanol and precipitated by adding acetone. The cleaned colloidal nanocrystals can be redispersed in hexane. Their particle sizes can be measured through transmission electron microscope (TEM), and their particle concentrations can be measured by a Perkin-Elmer inductively coupled plasma atomic emission spectroscopy (ICP-AES) instrument equipped with autosampler.

### Growth of Carbon Nanotube Carpets

Colloidal nanocrystals in hexane (20 μL) may be deposited on an alumina coated substrate (10×10 mm, Al₂O₃/SiO₂, 100 nm thick Al₂O₃ deposited through atomic layer deposition (ALD) on SiO₂ wafer). The colloidal nanocrystal solution on the substrate can be naturally dried at room temperature and then heated to 400° C. for 3 h to burn away oleic acid, the surface ligand on the nanocrystals. CNT carpets can be grown by a water-assisted hot-filament chemical vapor deposition (HF-CVD). The condition of gas flow for carpet growth chamber may be substantially 210 standard cubic centimeters (sccm) of H₂, 2 sccm of C₂H₂. The flow of water molecules can be generated by bubbling 200 sccm of H₂ through NANOpure water at room temperature. The total pressure under the gas flow condition may be 1.4 Torr. A higher pressure (25 Torr) was used to initiate CNT growth on the surface of the nanocrystals. With the gas pressure 25 Torr, the nanocrystal deposited Al₂O₃/Si wafer can be placed in the loading chamber and moved into the growth chamber. The reactor pressure can be reduced to 1.4 Torr after 30 s in the hot zone. The iron oxide nanocrystals deposited on the wafer can be reduced to iron particles using atomic hydrogen (H) generated through H₂ dissociation on a hot filament (0.25 mm tungsten; the current, voltage, and power may be substantially 7.5 A, 6.0 V, and 45 W, respectively). The hot filament can be left on for 30 s and then turned off. CNTs can be grown for 15 min at 750° C.

### Scanning Electron Microscope

Scanning electron microscope (SEM) samples can be placed on 45° SEM mounts, and SEM images taken by FEI Quanta 400 field-emission SEM at 10.0 kV. The height of CNT carpet may be measured by Image-Pro Plus 5.0.

### Transmission Electron Microscope

TEM specimens for iron oxide can be made by dropping the solution on ultrathin carbon type-A 400 mesh copper grids and dried naturally. CNTs grown on the substrate can be gently transferred onto Lacey Formvar/carbon, 300 mesh copper grids to make the CNT specimens. The TEM micrographs may be taken on a JEOL 2100 field-emission gun TEM operated at 200 kV with a single tilt holder. The size and size distribution data can be obtained by counting >1000 nanocrystalline particles using Image-Pro Plus 5.0.

### Raman Spectroscopy

The Raman spectra can be collected with a Raman spectrometer. CNT carpet samples can be placed on a glass slide, and a 785 nm laser introduced on the top of the CNT carpets. The induced laser polarization can be parallel to the alignment of the carpet. The IG/ID of each sample may be the average number from three different spots of CNT carpet.

### Calculation of Surface Coverage of Nanoparticles.

To obtain nanoparticle concentrations, ICP analysis of total iron concentration in solution may be used after the digestion of particles with nitric acid. In the calculation, an assumed particle volume of substantially 4/3π3 may be used, where r is the average radius of the nanocrystal as determined by TEM measurements, counting over 1000 particles; then, take the density of Fe₃O₄ (5.1 g/mL) or AlFe₂O₄ (4.6 g/mL) and calculate the particle weight. As an example, the volume of a 4.0 nm diameter particle of AlFe₂O₄ may be substantially 3.35×10-20 ml, which provides a total mass per particle of 1.5×10-19 g. Using this data and Avogadro's number, find that 40 ppm of iron in a solution results in a nanoparticle concentration of substantially 4.5×1017 nanoparticles/L (755 nM). If 20 μL of nanoparticle solution can be evaporated onto the substrate (1 cm×1 cm, alumina-coated Si wafer), then a surface coverage of nanoparticles substantially 9.0×1012 nanoparticles/cm² may be found.

### Calculation of the Diameter of Zerovalent Iron

The diameter of the reduced nanocrystal may be calculated starting from the average diameter of AlFe₂O₄ nanocrystal observed by TEM and the density of Fe₃O₄ (5.1 g/mL) and AlFe₂O₄ (4.6 g/mL). For example, the volume of 4 nm AlFe₂O₄ nanocrystal may be substantially 3.35×10-20 mL. The volume of this nanocrystal can be converted to mass of the particle, which equals substantially 1.54×10-19 g. Because the mass fraction of Fe in AlFe₂O₄ can be ˜0.57 (the molecular weights of Al, Fe, and O are 26.98, 58.93, and 15.99 g/mol, respectively), the mass of Fe can be 8.79×10-20 g. The calculated mass of iron can be converted to volume using the density of iron (7.8 g/mL) giving a final diameter of 2.78 nm. This number can be 30% less than the original diameter of the 4.0 nm AlFe₂O₄ nanocrystal.

Results for Control over the Diameter, Length, and Structure of the Carbon Nanotube

Monodisperse nanocrystals prepared via colloidal chemical methods can be used as precursors for the small iron particles necessary for CNT growth. These materials can be produced with diameters ranging from substantially 4 to 40 nm and also with size distributions generally under 10% on the diameter. For this effort, the conventional iron oxide synthesis has been expanded to incorporate aluminum, yielding similar sized and highly uniform aluminum ferrite nanocrystals under the appropriate conditions. Specifically, for the work described, three sizes of aluminum ferrite may be used (4.0±0.4; 9.5±0.7; 14.1±1.1 nm) and six sizes of iron oxide (4.3±0.5; 10.2±0.7; 16.0±1.4; 23.9±2.2; 32.1±2.5; and 38.4±3.3 nm). All particles may be stabilized by oleic acid coatings that rendered them well-dispersed and non-aggregating in hexane.

All diameters and compositions of catalyst precursors formed CNTs using a water-assisted CVD process. The hexane solvent can be evaporated away from nanocrystal suspensions applied to alumina substrates, resulting in a submonolayer of particles; exposure of these substrates to both acetylene and water at substantially 750° C. can result in the production of CNTs. Both the size and composition of the catalysts can have a significant effect on the diameter, wall number, and carpet height, as discussed herein. Additionally, for the largest size (for example, 38 nm diameters) of precursor catalyst, the CNT carpet height may be significantly reduced.

Within these dense carpets are many individual CNTs, and TEM can be applied to quantify their outer diameters. The larger catalyst particles can yield CNTs with larger diameters. In experiments, over 300 CNTs were measured to arrive at the average outer diameter; assuming a normal distribution, this can be appropriate sampling to specify with good confidence (95%) the average diameter. Qualitatively, it can be apparent in the images that the diameter of CNT increases as the diameter of the catalyst increased. For example, a 4.0 nm diameter aluminum ferrite nanocrystal produced mainly single- and double-walled CNT with 3.3 nm outer diameter; in contrast a larger iron oxide particle (d=16.0 nm) produced more multiwalled materials with diameters of 12.1 nm. Note that the precursor catalysts are fully reduced to the zerovalent metal under the CNT growth conditions; leading to a 30% reduction in their original oxidized diameters. Below 16 nm, the correlation between the calculated iron catalyst diameter and the CNT diameter can be substantially one for both iron oxide and the aluminum ferrites. Also, in agreement with past work is the observation that the tube diameter can be fixed by the particle diameter; this suggests that the growing carbon tube forms on opposite sides of the metal catalyst.

For the three largest catalysts the relationship between the nanoparticle diameter and CNT diameter may be much less pronounced. The trends observed for smaller precursor catalysts are distinctly different from that seen in the largest samples; the difference in CNT diameters when grown from 23 and 38 nm iron oxide nanocrystals may be substantially 4 nm. Also, for larger sizes the growth rates of the tubes are reduced, and there may be more evidence of iron wicking into the tube ends. Several researchers have suggested that iron must be fully molten to allow for the rapid diffusion and migration of graphitic materials to opposite sides of catalysts. The larger nanocrystals may not be completely molten at the 750° C. used for CNT growth. Bulk iron has a melting point of 1535° C. Smaller nanocrystals are known to have a reduced melting point due to their high surface energies; however, this effect may be minimal (<10%) for iron nanocrystals with diameters larger than substantially 15 nm. It is noted that for CNT grown from the larger catalysts the breadth of the CNT diameter distribution can be notably broader than that found for CNT grown from smaller materials. This is consistent with the observation that when catalyst diameters are large enough the CNT diameter may no longer be defined by the particle's diameter. Multiple nucleation sites on the larger particles and the more random location of the growing tube walls contribute to the less uniform materials.

The CNT produced via aluminum ferrite precursors, as compared with the iron oxide system, may reveal improvement in the diameter dispersion of the CNT. The most uniform CNTs may be produced with the aluminum ferrite nanocrystals; the iron oxide nanocrystals of similar sizes may be slightly larger outer diameter distributions. Colloidal nanocrystals start wetting at CNT growth temperatures and can be adhered on the wafer having crystal-to-liquid state and initiating carbon nucleation and growth process. In this process, aluminum in the nanocrystal may inhibit ripening of particles as it migrates to the alumina surface at high temperatures; the aluminum may diffuse out of the particle and interact with the free available oxygen. Al—O has a far more favorable bond strength than Fe—O (210 kJ/mol higher) because of its smaller ionic radius (Al³⁺: 53.5 μm, Fe³⁻: 64.5 μm, O²⁻: 126 μm). This high bonding energy increases the melting point, and catalyst ripening may be highly prevented by this strong aluminum oxygen bonding between aluminum ferrite nanocrystals and the alumina wafer in the nanocatalyst wetting. The catalyst diameter and composition also controls the amount and number of single, double, triple, and multiwalled CNT; as anticipated, single-walled nanotubes (SWNTs) are most prevalent when smaller nanocrystals are used. The very smallest nanoparticles (for example, d=4 nm) formed single-, double-, and triple-walled CNTs, and the percentage of multiwalled tubes can increase smoothly as the diameter of the catalyst increased. This parallels observations from thin films and catalyst islands deposited via gas-phase methods; SWNTs were grown only by a thin 2 nm iron layer, whereas more double-walled and multiwalled nanotubes were observed when iron layers were nearly 3 nm in thickness. Using a process similar to the one applied here, Nishino et al. showed that with 3.2 nm Fe/Mo high fractions of SWNT were also observed (Nishino et al., 2007, 111, 17961-17965). Here a significant fraction of SWNT even for precursor catalysts as large as 4 nm, and for catalysts much larger than this, wall numbers increase substantially. To increase the amount of SWNTs further, it may be necessary to slow the rate of introduction of the carbon source (C₂H₂) and use exclusively aluminum ferrite materials. In experiments, over 60% of the carpet material was SWNT when aluminum ferrite particles were used with a slow acetylene flow rate (0.5 sccm). In contrast, 55% of the carpet material was double-walled for the same catalyst at reactant flow rates (2.0 sccm). Zhang et al. found that slow introduction of carbon feedstock not only reduces the incidence of increased wall number but also reduces the amount of amorphous carbon (Zhang et al., J. Phys. Chem. C 2008, 112, 12706-12709). By introducing C₂H₂ at a slower rate, there may be fewer collisions of C₂H₂ with the side walls of growing CNTs. A potential disadvantage of relying on slower reaction rates to form more SWNTs can be the reduction in the carpet heights. Here the carpet height decreased from 9 to 3 μm as the acetylene flow rate was decreased from 2.0 to 0.5 sccm, respectively.

CNT quality can also be an important feature of these materials; amorphous carbon and disordered carbon in the tubes can limit desirable electronic and mechanical properties. Experimentation shows that films grown from smaller catalysts may lead to notably higher quality materials for all conditions. The quality of the CNTs grown from both aluminum ferrite and iron oxide nanocrystals may be characterized by Raman spectroscopy. The D (˜1340 cm⁻¹) band results from defects on nanotubes such as heteroatoms, vacancies, heptagon-pentagon pairs, impurities (amorphous carbon), and forming wall-wall interactions; the G (˜1590 cm⁻¹) band indicates the presence of well-ordered sp² carbons. Therefore, the G to D ratio can act as a common standard for characterizing CNT quality. It may also be that in larger particles carbon supersaturation may not result in the formation of graphitic caps because the materials are not fully molten; this may result in amorphous carbon deposition.

Experimentation demonstrated that the inclusion of the dopant aluminum in the iron catalysts can cause significant improvement in the quality of the CNTs. For all three sizes, the aluminum ferrite nanocrystals formed CNT with very high quality (G/D=11.4) as compared with the best CNT formed from pure iron oxide crystals (G/D=9.8). Additionally, the tube quality was less sensitive to the aluminum ferrite catalyst diameter than CNT grown from pure iron oxide. For these doped nanocrystals, 30% of the iron may be substituted with aluminum; after the particles are fully reduced, this may result in substantially smaller catalyst diameters than those catalysts formed from pure iron oxide. Smaller catalysts can lead to less multiple nucleation and more efficient nucleation of the graphitic shells necessary for high-quality CNT growth.

The quality of the CNT films may also be a sensitive function of both the surface coverage of nanocrystals and the reaction pressures; in general, monolayer coverages with no aggregation can be the best conditions for growth. In experiments, the highest G to D ratio was measured from the CNT carpets grown when the surface of wafer was covered by a monolayer of aluminum ferrite (750 nM, 9.03×1012 nanocrystals/cm²). In addition, CNT carpets had higher G to D ratios at 1.4 Torr (IG/ID=11.4) than those grown at 25 Torr (IG/ID=1.3). Pint et al. reported controllable CNT quality depending on reaction pressure (Pint et al., J. Phys. Chem. C 2008, 112, 14041-14051). It was noted that while growing CNT carpets certain amounts of C₂H₂ might be consumed in the formation of amorphous carbon or increasing the number of walls rather than letting a few walls of CNTs grow vertically. The increase in the number of walls may be related to the diffusivity and solubility of the carbon in the activated catalyst as well as its shape. Basically, fast diffusion and a high solubility of carbon can increase the number of walls rather than grow longer CNTs. Therefore, at higher pressures, poorer quality CNTs may be prepared, as evidenced by the reduced G/D ratio (IG/ID=1.3).

Finally, in experiments, it was determined what conditions may promote the formation of thick CNT films. In general, surface coverages of precursor catalysts near a monolayer and higher reaction pressure promoted carpet growth. At 1.4 Torr for 15 min, CNT carpet's height increased from 1.8 to 22.1 μm when the nanocrystal concentration decreased from 6000 (7.22×1013 nanocrystals/cm2) to 750 nM (9.03×1012 nanocrystals/cm2). CNT carpet was the thickest when the nanocatalyst layer on the wafer closed to a monolayer (750 nM, 9.03×1012 nanocrystals/cm2), and this catalyst coverage yielded 280.3 μm at 25 Torr. A fast supply of large quantity of carbon source at high pressure with perfect coverage of catalyst can build up carbon structure fast and result in thicker nanotube carpets.

Even thicker films may result when using smaller catalysts, and the inclusion of an aluminum dopant can lead to even thicker films. CNT carpet heights can be from 0.1 to 5.3 μm as the concentration of iron oxide nanocrystals decreased from 6000 (7.22×1013 nanocrystals/cm2) to 750 nM (9.03×1012 nanocrystals/cm2). However, CNTs from aluminum ferrite nanocrystals may be grown from 7.6 to 54 μm at the same surface coverage of nanocrystals. The strong interaction between aluminum containing nanocrystals and the substrate may prevent the removal of catalysts by penetration into the substrate (forming an alloy with the support substrate) and after all increase the lifetime of catalysts. Also, aluminum ferrite nanocrystal has less active iron than equivalent iron oxide material; this also may result in a smaller active catalyst and faster carpet growth. There can also be strong size dependence apparent in these data: larger particles produce more slowly growing carpets.

In summary, uniform iron oxide and aluminum ferrite nanocrystals formed in a conventional wet chemical method may be applied as precursor catalysts for the growth of CNT. The application of colloidal nanocrystals may offer the opportunity to tune the resulting CNT structure through both the reaction conditions as well as the composition, size, and coverage of the precursor catalysts. For example, as nanocatalysts increase in dimensions they may produce increasingly larger CNT. Also, the numbers of walls in the final CNT product can be a sensitive function of the starting catalyst size: under the appropriate reaction conditions, the smallest catalysts may yield materials with over 60% single-walled CNTs. More typically, samples were mixtures of double, triple, and larger multiple tubes. Finally, the incorporation of aluminum into the catalyst resulted in both higher quality as well as thicker carpets. These data illustrate that catalyst surface coverage, dimension, and composition can be used to tailor the structural features as well as the quality of CNT carpets.

### Electrochemical Reduction of Cr^{VI}

The first step of electrochemical treatment of Cr^{VI}-contaminated water, namely the reduction of Cr^{VI} to Cr^{III}, was achieved by negatively polarizing the CNT cathode. The Cr^{VI}-contaminated water was simulated using an aqueous solution containing K₂Cr₂O₇ and Na₂SO₄. In this solution system, the increase of pH by reaction 1 near the cathode can lead to the formation of Cr(OH)₃ colloids and eventually the passivation of cathode by polynuclear Cr(OH)₃Cr(OH)CrO₄ coating. The presence of sulfate can prevent the formation of colloids and coating by coordinating with Cr^{III} in solution. The use of monovalent K⁺ and Na⁺ as balancing cations minimizes the competition with Cr³⁺ in electrosorption, where ions with greater ionic charges and smaller hydrated radii are preferably adsorbed. Compared to K⁺ and Na⁺, Cr³⁺ has a similar hydrated radius (461 pm vs 331 pm for K⁺ and 358 pm for Na⁺) but a much greater amount of ionic charge; therefore, K⁺ and Na⁺ may not interfere with the electrosorption of Cr³⁺.

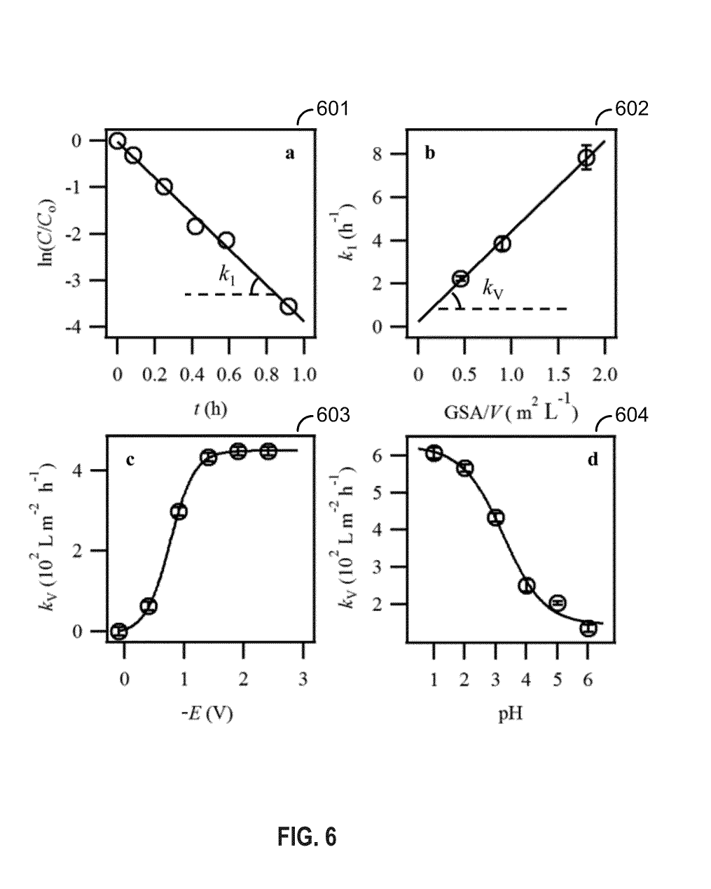

FIG. 6 shows an example obtained using the electrode with GSA=9 cm² and sESA=5.7(±0.3) m² m⁻². Graph 601 provides an estimation of pseudo-first-order rate constant for Cr^{VI} reduction. Graph 602 provides its dependence on reaction volume V, and the dependence of volume normalized pseudo first order rate constant on 603 potential and 604 pH. Solution pH for 601, 602, and 603: 3. Solution volume for 601, 603, and 604: V=100 mL. Potential for 601, 602, and 604: −1.4 V. Electrode: L=14(±1) μm. In a solution containing ca. 9 mg L⁻¹ K₂Cr₂O₇ and 10 g L⁻¹ Na₂SO₄ (100 mL at pH 3), the logarithmic reduction of Cr^{VI} concentration exhibits pseudo first order kinetics when the electrode is polarized at E=−1.4 V (vs the standard hydrogen electrode; graph 601):

ln(C/C₀)=−k₁t (6)

Where C0 and C are initial and residual concentrations, t is time, and k₁ is the rate constant. For volume V=50-200 mL, k₁ may be found to correlate inversely with V (graph 602), indicating

k₁=k_{υ}GSA/V (7)

The volume normalized pseudo-first-order rate constant (k_{V}) depends on both E and pH. With the increase of polarization (i.e., E becomes increasingly negative), k_{V} increases rapidly from zero at E=0 to 432(±11) L m⁻² h⁻¹ at E=−1.4 V (see, 603). Further increase of polarization does not lead to further increase of k_{V}, suggesting that the kinetics of Cr^{VI} reduction has entered an ESA-controlled regime. As pH increases, k_{V} decreases rapidly from 606(±15) L m⁻² h⁻¹ at pH=1 to 135(±10) L m⁻² h⁻¹ at pH=6 (see, 604), consistent with reaction 1 that involves proton as a reactant. At E=−1.4 V, hydrogen bubbles formed by the reduction of water can be seen evolving near the cathode. This can be consistent with the H2 evolution potential of −0.63 V measured for CNT electrodes in solutions without Cr^{VI}.

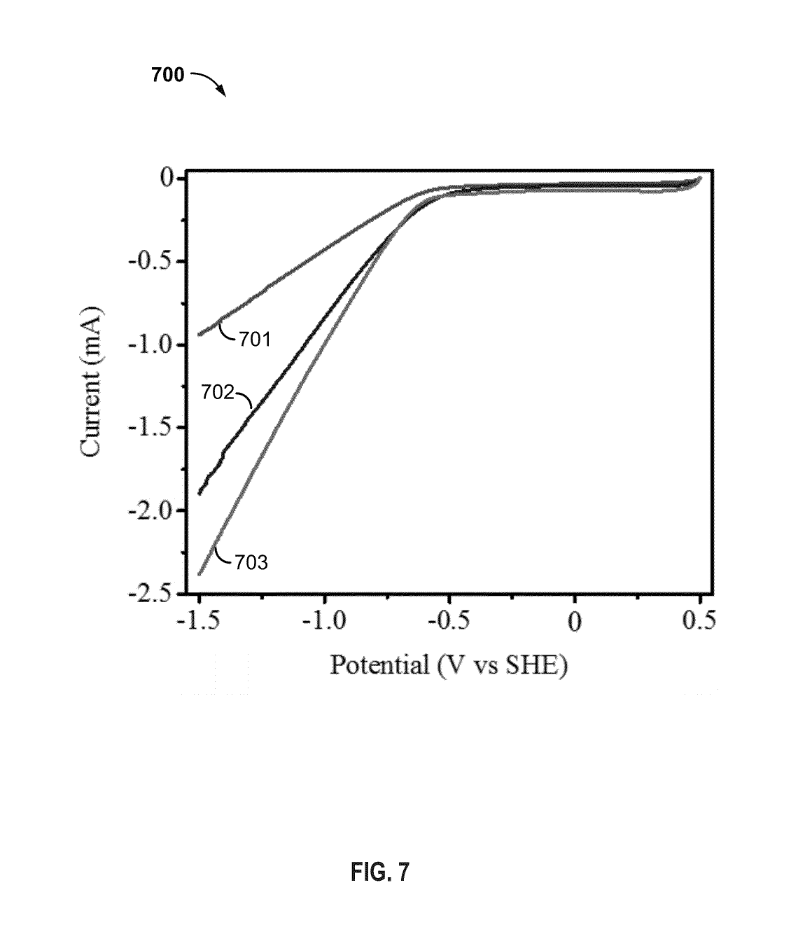

FIG. 7 illustrates the linear sweep voltammograms of CNT electrodes for water reduction. CNT electrodes with different CNT lengths are distinguished in the lines on graph 700. For example: line 701, 5(±1) μm; line 702, 14(±1) μm; and line 703, 24(±4) μm. Solution conditions: 10 g L⁻¹ Na₂SO₄ and pH 0. Scan rate: 10 mV s⁻¹. SHE: Standard hydrogen electrode. The reduction of water, which increases with increasing the negative potential on the cathode produces highly reactive atomic hydrogen radicals that reduce Cr^{VI} indirectly in addition to the direct reduction of Cr^{VI} on the CNT surface. The unreacted hydrogen radicals combine into hydrogen gas. Thus, in one aspect, the embodiments relate to a process for producing hydrogen gas.

### Hydrogen Gas Production

A typical electrochemical cell may have a positively charged anode and a negatively charged cathode. The anode and cathode are typically submerged in a liquid electrolytic solution which may be comprised of water and certain salts, acids or base materials. Generally speaking, gaseous oxygen can be released at the anode surface while gaseous hydrogen can be released at the cathode surface. A catalyst such as lead dioxide may be used to coat the anode to get greater ozone production. Platinum, carbon, or nickel and its alloys may be used as hydrogen-evolving cathodes. Alternatively, an air or oxygen depolarized cathode may be employed which may greatly reduce the cell voltage and enhance the overall energy efficiency of the process. The anode substrate may be another material such as titanium, graphite, or the like.

### Desalination

In one embodiment, carboxylic groups are created on the carbon nanotube rim by the etching processes used for opening the CNTs and for removing the excess filling matrix eventually covering the tips. These etching processes include argon ion milling, reactive ion etching, oxygen plasma, water plasma, and air plasma. When in contact with an aqueous salt solution at a pH larger than the pKa of an acid, for example, carboxylic acid, these functional groups are ionized and form a rim of charges at the carbon nanotube entrance.

In some embodiments, the nanotube can be functionalized with the same or different group. In some embodiments, the nanotube can be functionalized with the same group. In some embodiments, the at least one end or the pore entrance of at least one of the nanotube can be functionalized with a charged group. Examples of charged groups attached to the end or the pore entrance of the nanotube, include, but are not limited to, sulfonate, phosphonate, ammonium, carboxylate, etc. In some embodiments, the at least one end or the pore entrance of at least one of the nanotube can be functionalized with a non-charged group. Example of non-charged group includes, but is not limited to, non-charged dendrimer.

In some embodiments, the nanotube can be functionalized with an acidic group or a basic group. In some embodiments, the nanotube can be functionalized with a permanent charged group. In some embodiments, the nanotube can be functionalized with a group selected from carboxylic acid, sulfonic acid, phosphonic acid, amine, amide, polymer, dendrimer, and a polyelectrolyte. In some embodiments, the nanotube can be functionalized with an amide or polyamide. In some embodiments, the nanotube can be functionalized with a short oligomer or a long oligomer of, for example, polyethylene glycol (PEG) polymer. In some embodiments, the nanotube can be functionalized with polyelectrolytes. In some embodiments, the nanotube can be functionalized with a dendrimer. Example of dendrimer includes, without limitation, poly(amidoamine) (PAMAM).

The functionalization of the nanotubes enhances rejection of the ions in the fluid, enhances selectivity of the membranes, and/or reduces fouling of the membranes.

For carbon nanotube pores with substantially sub-6 nm diameter, steric hindrance and/or electrostatic interactions between the charged functionalities on the membrane and ionic species in solution enable effective rejection of ions during salt solution filtration.

In some embodiments, the nanotube can be functionalized with polymers, branched polymers, dendrimers, or poly(m-aminobenzene sulfonic acid). In some embodiments, the nanotube end or pore entrance can be modified by attaching a short chain or long chain primary amine through an amide bond.

In some embodiments, the nanotube can be functionalized with a polyelectrolyte, such as a single stranded or double stranded DNA (deoxyribonucleic acid). DNA-based gating of nanotube membranes can be based on attaching a short single-stranded DNA hairpin to the mouth of the CNT membrane pore. The ssDNA (single strand DNA) can (according to the MD simulations, H. Gao et al., Nano Lett. 3,471 (2003)) spontaneously insert into the CNT pore channel. In the normally-closed configuration the mouth of the nanotube can be blocked by a partially-inserted DNA hairpin attached to the nanotube mouth. Addition of a complementary DNA strand extracts the DNA strand from the channel and opens up the pore. In the normally-open configuration, the DNA hairpin can be complexed with the slightly longer complementary DNA; addition of the reverse complementary sequence strips the complement off the hairpin and causes the hairpin to block the nanotube opening. The benefits of this approach include the ability to regulate the permeability of CNT membrane using very specific sequences of DNA. Possible uses of this embodiment range from timed delivery of reagents or drugs, to creation of “smart surfaces” that may release antibiotics, antidotes or other chemicals when triggered by presence of a specific pathogenic DNA sequence outside of the membrane.

In some embodiments, a short section of the carbon nanotube, embedded in a matrix, can be removed at the entrance. That region of the matrix can be modified to create a gate region. The walls of the pore formed in the matrix are used to anchor chemical groups allowing for control of the length of the gate region.

The at least one end or the pore entrance of at least one of the nanotubes can be functionalized in various ways. In some embodiments, the functional groups are attached to the end or tips of the CNTs. In some embodiments, CNTs are preferentially etched, leaving a pore of the matrix above it and the functional groups are attached to the sidewalls of the pore created in the polymer matrix. In some embodiments, the inner side walls of the CNTs are functionalized by breaking the carbon-carbon bonds and attaching functional groups, such as for example, amide groups or charged groups such as tertiary amine, etc. In some embodiments, both the matrix surface and the CNT mouth are functionalized with the ion-rejecting compound or the charged group. In some embodiments, the nanotube mouth can be functionalized with a charged group and the matrix surface can be functionalized with the foulant-rejecting moiety (such as PEG) to create a dual-functionalized membrane.

In some embodiments, the functionalization of at least one end or pore entrance of at least one nanotube in the membrane provides selectivity to the membrane in terms of the nature of the ions that can be removed from the water. For example, the nanotube end functionalized with carboxylate anion may selectively reject anions from water and the nanotube end functionalized with an amino cation may selectively reject cations from the water.

In some embodiments, the membranes possess temporarily protected pores. For example, a group that closes CNT and can be released by external stimulus is useful as a way to protect the inside of the CNT from being filled or damaged during membrane fabrication, storage and transportation. This kind of group protection can be realized using photo-cleavable ligands. Example of photo-cleavable ligand includes, but is not limited to, 4-t-butyl-a nitrobenzyl cleavable with UV light.

In each of the above embodiments, it should be understood, although not explicitly stated that the nanotubes are functionalized with from about 5%-100% of the site available for functionalization; from about 10%-90%; from about 25%-75%; from about 50%-75%; or from about 50%-100%. In some embodiments, functionalization of the nanotubes with just one functional group may be sufficient to impart properties to the membrane. In some embodiments, all the available sites on the nanotubes are functionalized to impart properties to the nanotubes. In some embodiment, the functionalization of the nanotube in a membrane provides an enhanced selectivity in the transport of the fluid than a non-functionalized nanotube. In some embodiment, the functionalization of the nanotube in a membrane provides an enhanced rejection of the salt from a salted water than a non-functionalized nanotube.

In each of the above embodiments, it should be understood, although not explicitly stated that the average pore sizes of the carbon nanotube membranes can be for example about 0.5 nm to about 6 nm, or about 1 nm to about 2 nm. In one embodiment, they are on average less than about 6 nm, but still of sufficient internal diameter to allow gas and liquid molecules to pass through them. Thus, alternative embodiments include nanotubes having average pores sizes of less than about 6 nm, or alternatively, less than about 5 nm, or alternatively, less than about 4 nm, or alternatively, less than about 3 nm, or alternatively, less than about 2 nm, or alternatively, less than about 1 nm, or alternatively between about 0.5 nm and about 6 nm, or alternatively between about 1 nm and about 4 nm and yet further, between about 1 nm and about 3 nm or yet further, between about 0.5 nm and about 2 nm.

In each of the above embodiments, it should be understood, although not explicitly stated that the number of pores having the aforementioned pore sizes in the membrane can be from greater than about 40%, or alternatively greater than about 45%, or alternatively more than about 50%, or alternatively, more than about 55%, or alternatively, more than about 60%, or alternatively more than about 65%, or alternatively more than about 70%, or alternatively more than about 75%, or alternatively more than about 80%, or alternatively more than about 85%, or alternatively more than about 90% or alternatively, more than about 95%, each of the total number of pores in the membrane. Typically, pore size may be determined by TEM (Transmission Electron Microscope) or Raman spectroscopy method, although other methods are known in the art.

The CNTs in the membrane can be substantially single walled nanotubes or alternatively double walled nanotubes or alternatively multiwalled nanotubes or yet further comprise a combination of any of single-, double- or multiwalled. An array of substantially any one type of carbon nanotube (for example, single, double or multi) intends greater than about 70%, or 80%, or 90% of the nanotubes in the array are of that type.

In one embodiment, the nanotubes can have open ends on one side, or on each side of the membrane. Opening can be determined by for example fluid transport through the carbon nanotube as well as analytical methods such as nanoscale electron microscopy. Nanotubes can be used in applications such as composites or cold emitters wherein the nanotube may be open on one side or may be open on neither side.

In some cases, CNTs can also comprise catalyst nanoparticles at one end. For the purpose of illustration only, catalyst nanoparticles include, but are not limited to pure or alloyed iron, cobalt, nickel, molybdenum and platinum. In one embodiment, more than 10%; more than 20%; more than 30%; more than 40%; more than 50%; more than 60%; or more than 70% of the nanotubes are free of catalyst nanoparticles used for carbon nanotube formation. In a further embodiment, more that 80%, or yet further, more than 90%, or even further more than 95% of the nanotubes are free of catalyst nanoparticles used for carbon nanotube formation.

The CNTs in a membrane also can be characterized by an areal density. For example, areal density can be for example at least 1×10¹⁰/square centimeter, or alternatively at least 1.5×10¹⁰/square centimeter, or alternatively at least 2×10¹⁰/square centimeter, or alternatively at least 2.5×10¹⁰/square centimeter, or alternatively, at least 3×10¹⁰/square centimeter, or alternatively at least 3.5×10¹⁰/square centimeter, or alternatively at least 4×10¹⁰/square centimeter.

The CNTs in a membrane also can also be characterized by a charge density. For example, charge density can be for example at least about 0.5-4 mM, or alternatively at least 1-3 mM, or alternatively at least 2-3 mM, or alternatively at least 1-2 mM, or alternatively, at least 1.5-3 mM, or alternatively at least 0.5-2 mM, or alternatively at least 1.5-2.5 mM.

The CNTs can be characterized by an average length. The upper end on length may not be particularly limited and CNTs hundreds of microns long, such as 500 microns long, can be made. For example, average length can be about 0.1 microns to about 500 microns, or about 5 microns to about 250 microns, or about 0.1 microns to about 5 microns, or about 0.2 microns to about 20 microns, or about 0.2 microns to about 10 microns, or about 0.2 microns to about 5 microns. Average length can be greater than about 0.5 micron, or alternatively greater than about 1 microns, or alternatively, greater than about 3 microns, or alternatively, greater than about 4 microns, or alternatively, about 5 microns to about 100 microns, or alternatively, about 5 microns to about 150 microns, or alternatively, about 5 microns to about 50 microns, or yet further about 1 micron to about 50 microns. The CNTs arranged in an array can be characterized by high aspect ratio gaps between the individual CNTs, wherein the length may be much greater than the width. For example, aspect ratio of these gaps can be at least 1,000 length/width.

For the pore sizes described herein, efficient ion rejection may largely be due to the electrostatic repulsion between the charges strategically placed on the through-pore entrance and the co-ions in solutions. Efficient ion rejection can be achieved for millimolar or sub-millimolar salt concentration. Increasing the number of charges at the nanopore entrance by targeted functionalization improves ion rejection performances. For larger pore diameters, rejection performances may degrade quickly with increasing nanotube size. In another embodiment, the charged carbon nanotube pores have a sub-nanometer diameter. For these carbon nanotube sizes, efficient ion exclusion can be obtained for much larger salt solution concentrations due to the simultaneous contribution of steric hindrance, size exclusion, and electrostatic repulsion mechanisms.

Pressure-driven filtration experiments, coupled with capillary electrophoresis analysis of the permeate and feed, are used to quantify ion exclusion in these membranes as a function of solution ionic strength, pH, and ion valence. In some embodiments, the carbon nanotube membranes exhibit ion exclusion as high as 98% under certain conditions. In some embodiments, the ion exclusion results may support a Donnan-type rejection mechanism, dominated by electrostatic interactions between fixed membrane charges and mobile ions, while steric and hydrodynamic effects may be minor or negligible.

A model of nanofluidic platform containing sub-2 nm carbon nanotube membranes fabricated by conformal deposition of silicon nitride on densely-packed, vertically-aligned carbon nanotube forests has been demonstrated (Holt J K, Park H G, Wang Y M, Stadermann M, Artyukhin A B, Grigotopoulos C P, Noy A, Bakajin O (2006) Fast mass transport through sub-2-nanometer CNTs. Science 312:1034-1037). The etching process can be used to expose and to selectively uncap the CNTs to introduce hydroxyl (OH), carbonyl (C═O), and carboxylic (COOH) functional groups at the nanotube entrance (Yang D Q, Rochette J F, Sacher E (2005) Controlled chemical functionalization of multiwalled CNTs by kiloelectronvolt argon ion treatment and air exposure. Langmuir 21:8539-8545; and Li P H, Lim X D, Zhu Y W, Yu T, Ong C K, Shen Z X, Wee A T S, Sow C H (2007) Tailoring wettability change on aligned and patterned carbon nanotube films for selective assembly. J Phys Chem B 111:1672-1678). In particular, ionization of these carboxylic groups provides a ring of negative charges at the pore entrance that may affect the ion transport through the nanotube pore.

### Membranes

In one aspect, there can be a membrane provided for an enhanced fluid transport containing a substantially vertically-aligned array of CNTs as provided herein and a matrix material disposed between the CNTs. In a particular embodiment, there can be provided a membrane for an enhanced fluid transport containing a substantially vertically-aligned array of CNTs functionalized at least one end of at least one of the nanotubes, wherein the nanotubes have average pore size of about 6 nm or less and a matrix material disposed between the CNTs.

In another embodiment, there can be a membrane provided for an enhanced transport of desalted water from salted water containing: a substantially vertically-aligned array of CNTs, wherein the nanotubes have average pore size of about 1-2 nm having at least one functionalized nanotube; and a matrix material disposed between the CNTs.

In another embodiment, the membranes may be used to selectively transport certain ions, but reject other ions across the membrane. This may be achieved by selecting a functional group at the end of the nanotube that rejects certain ions while allowing other ions to transport across the membrane.

In yet another embodiment, there may be a membrane provided for an enhanced transport of desalted water from salted water containing: a substantially vertically-aligned array of CNTs, wherein the nanotubes have average pore size of about 1-2 nm with a charge density of about 1-3 mM and have at least one functionalized nanotube; and a matrix material disposed between the CNTs.

In some embodiments, the membrane described herein provides an enhanced selectivity in the transport of the fluid larger than a non-functionalized nanotube. In some embodiments, the membrane described herein provides an enhanced rejection of the salt from a salted water than a non-functionalized nanotube.

These membranes can have pore sizes on the molecular scale (ranging from approximately 1 nm to approximately 2 nm). They are robust, mechanically and chemically stable. Enhanced gas transport through the membranes compared to other materials of similar pore size can be demonstrated. Molecular dynamics simulations predict high water flows through these materials too. Due to high molecular flux and possibility of size exclusion, the possible applications of these materials include but are not limited to: 1) Gas separations such as (but not limited to) removal of hydrocarbons, CO₂ sequestration; 2) water desalination/demineralization (described below); 3) dialysis; and 4) breathable material for protection from chemical and biological agents.

The nanoporous membranes can be fabricated from a variety of a substantially vertically aligned array of single wall, double-walled, or multi-wall CNTs, grown via an atmospheric pressure chemical vapor deposition process, as known in the art. For example, ethylene, hydrogen, and argon can be used as process gases, and a thin metal multilayer deposited on silicon can serve as the substrate to catalyze the growth. It can be the uniqueness of the metal catalyst layer that enables one to grow CNTs, including SWCNTs, in a substantially vertically aligned array, as opposed to growth in the plane of the substrate. This vertically aligned array of nanotubes typically has internal diameters ranging from, for example, 0.8-2 nm, a tube-tube spacing of less than 50 nm, preferably 1.0 to 5.0 nm, and a height (thickness) of 5-10 μm. MWCNT arrays may have internal diameters on the order of 5-20 nm.

Once grown, the nanotube array can be coated by a matrix material to immobilize the tubes and enable processing into a membrane. Matrix fill can be continuous or form a closed cell structure. A factor here can be the use of a conformal material that can fill the high aspect ratio (approximately 1000 length/diameter) gaps between these tubes, such that the CNTs serve as the only pores in the material. A variety of matrix materials, ranging from inorganic material to polymeric material (for example, parylene, polydimethylsiloxane, polyimide) may be used. Polymeric material includes, but is not limited to, linear polymers such as polyethylene, polyacrylates, or polystyrene and cross linked polymers such as epoxy resins. It can also be semi-permeable such as polyamide or non-permeable such as epoxy resin.

Examples of inorganic material include, but are not limited to, ceramics (for example, silicon nitride, silicon dioxide). The matrix material can also be for example an oxide material such as for example silicon or aluminum oxide. Silicon oxide materials can be made from, for example, (TEOS) tetraethyloxysilane. The matrix material may also include silicon from, for example, a silicon source. Polysilicon can be used.

Any number of additional matrix materials can be used which can have the functional characteristics of having negligible, low or high molecular permeability. In some embodiments, the matric material has a selective molecular permeability where it allows certain molecules to penetrate while preventing others. Other functional characteristics can include optical impermeability, or opaqueness, indicating transmitting negligible light intensity over a certain range of wavelengths, compared to the internal space of the CNTs. Matrix can also be transparent. The membrane can have a thickness of for example about 100 nm to about 2 microns, or about 400 nm to about 800 nm.

Low-stress silicon nitride and TEOS oxide (tetraethoxysilane oxide) have been successfully used to achieve conformal, void-free coatings on multiwall nanotube arrays (outer diameters of 20-50 nm), resulting in a high strength composite membrane. In addition to using CVD (Chemical Vapor Deposition) coatings, filling can be achieved using Atomic Layer Deposition. In some embodiments, the matrix material comprises a ceramic. In some embodiments, the matrix material comprises silicon nitride. In some embodiments, the matrix material comprises low stress silicon nitride. In some embodiments, the matrix material comprises a polymer. In some embodiments, the matrix material comprises TEOS oxide.

It is to be noted that ceramics like silicon nitride are particularly advantageous for desalting/demineralization applications, due both to their high temperature stability (films deposited at 800° C.) and solvent resistance (to strong acids/bases), which may facilitate removal of the organic and inorganic foulants on the membrane. Parylene has also exhibited conformal properties on multiwall CNT arrays, with both high temperature stability (melting point up to 420° C.) and solvent resistance.

Provided herein is a method for producing a CNT-based membrane using low-stress silicon nitride as a conformal matrix material. This method provides a graphitic CNT membrane using a ceramic matrix material. In contrast to polymer matrices, silicon nitride has a negligible molecular permeability, leaving the cores of embedded CNTs as the only pores in the membrane. In addition, the nanotubes can also serve as a template for the production of nanoporous silicon nitride since they can be selectively removed by oxidation. Another advantage of silicon nitride can be its vapor phase deposition. Materials deposited in the liquid phase such as spun-on polymers may involve elaborate curing processes to reduce CNT agglomeration and ensure retention of alignment.

In some embodiments, the matrix material has negligible molecular permeability. In some embodiments, the matrix material can be a rigid material. In some embodiments, the membrane has a thickness of about 0.1 microns to about 2 microns. In some embodiments, the matrix material has a thickness of about 400 nm to about 800 nm.

It may be desirable to ensure adhesion between the carbon nanotube and the matrix such that the composite material as a whole can be mechanically robust. In some embodiments, the matrix material encapsulates the CNTs. In some embodiments, the matrix material conformally coats the CNTs. In some embodiments, the matrix material can be free of gaps between the outer surface of the nanotubes and the matrix material. To this end, tensile strain tests on the material, as well as nanoindentation tests to examine closely the nanotube/matrix interface can be carried out. In some embodiments, the membrane does not fracture when tested with a one atmosphere pressure drop.

In one aspect, the membranes are characterized functionally in that they may not pass particles or nanoparticles such as for example 100 nm or 25 nm fluorescently labeled polystyrene beads or metallic nanoparticles of for example size of 2, 5, or 10 nm. In additional, microscopic and spectroscopic techniques using AFM (atomic force microscopy) and UV-VIS spectroscopy can functionally characterize the exclusion of 2 nm gold colloidal nanoparticles in membrane permeation.

In some embodiments, the membrane does not pass 100 nm fluorescently-labeled polystyrene beads. In some embodiments, the membrane does not pass 25 nm fluorescently-labeled polystyrene beads. In some embodiments, the membrane does not pass 2 nm, 5 nm, or 10 nm gold nanoparticles.

In some embodiments, the gaps in the nanotubes are high aspect ratio gaps of about 1,000 length/diameter or less. In some embodiments, the gaps are high aspect ratio gaps of at least about 100 length/diameter.

In some embodiments, the membrane provides enhanced gas transport compared to the Knudsen transport prediction for same sized pores. In some embodiments, the membrane provides enhanced gas transport compared to the Knudsen transport prediction for same sized pores, wherein the enhancement can be at least three orders of magnitude for an air flow rate. In some embodiments, the membrane provides enhanced gas transport compared to the Knudsen transport prediction for same sized pores, wherein the enhancement can be at least 16 times that for an air flow rate. In some embodiments, the membrane provides enhanced gas transport compared to the Knudsen transport prediction for same sized pores, wherein the enhancement can be at least 50 times that for an air flow rate.

In some embodiments, the membrane provides enhancement of water flow over no-slip, hydrodynamic flow prediction. In some embodiments, the membrane provides enhancement of water flow over no-slip, hydrodynamic flow by at least 10 times. In some embodiments, the membrane provides enhancement of water flow over no-slip, hydrodynamic flow by at least 500 times.

In some embodiments, the membrane provides an air permeability of at least one cc/s-cm2-atm and a water permeability of at least one mm³/s-cm²-atm. In some embodiments, the membrane provides an air permeability of at least two cc/s-cm²-atm and a water permeability of at least two mm³/s-cm²-atm. In some embodiments, the membrane provides a gas selectivity relative to helium which can be higher than that from a Knudsen model.

In each of the embodiments described herein, it should be understood, although not explicitly stated that the nanotubes have a height of about 0.2 microns to about 5 microns, and the matrix material comprises a ceramic or polymer. In some embodiments, the nanotubes have a height of about 0.2 microns to about 5 microns, and the matrix material comprises a polymer. In some embodiments, the nanotubes have a height of about 0.2 microns to about 5 microns, and the matrix material comprises a ceramic. In some embodiments, the membrane provides enhanced gas transport compared to Knudsen transport prediction for same sized pores.

In some embodiments, there can be provided a membrane for an enhanced transport of desalted water from salted water containing a substantially vertically-aligned array of CNTs, wherein the nanotubes have average pore size of about 1-2 nm having at least one functionalized nanotube; and a matrix material disposed between the CNTs, wherein the membrane provides an enhanced selectivity in the transport of desalted water from salted water than a nanotube without a functionalized tip.

In some embodiments, there can be provided a membrane for an enhanced transport of desalted water from salted water containing: a substantially vertically-aligned array of CNTs, wherein the nanotubes have average pore size of about 1-2 nm having at least one functionalized nanotube; and a matrix material disposed between the CNTs, wherein the membrane provides an enhanced rejection of the salt from a salted water than a nanotube without a functionalized tip.

In some embodiments, there can be provided a membrane for an enhanced transport of desalted water from salted water containing: a substantially vertically-aligned array of CNTs, wherein the nanotubes have average pore size of about 1-2 nm with a charge density of about 1-3 mM and have at least one functionalized nanotube; and a matrix material disposed between the CNTs, wherein the membrane provides an enhanced rejection of the salt from a salted water than a nanotube without a functionalized tip.

After coating, the excess matrix material can be removed from the membrane, and the CNTs can be opened, as they are initially capped at the top and blocked at the bottom with catalyst particles. This can be easily achieved by use of a plasma etching process.

In some embodiments, there can be provided a nanoporous membrane prepared by the methods described herein. In some embodiments, the substantially vertically aligned carbon nanotube array in the nanoporous membrane can be a single wall array, and the nanotubes have diameters on the order of 0.8 nm to 2 nm, a tube-tube spacing of less than 50 nm, and a height of 5 microns to 10 microns. In some embodiments, the vertically aligned carbon nanotube array in the nanoporous membrane can be a multi wall array, and the nanotubes have diameters on the order of 5 nm to 10 nm, a tube-tube spacing of less than 5 nm, and a height of 5 microns to 10 microns.

Another embodiment can be a fabric containing the membrane having the array of nanotubes as provided herein and a porous polymer or fiber fabric supporting material. Articles can include articles that comprise a plurality of membranes including for example chips containing a plurality of membranes, as well as systems and devices wherein membranes are placed on top of each other in multilayer formats.

### Making Membranes

Fabrications methods for the membranes provided herein, can comprise at least two general steps. In a first step, the array of substantially vertically aligned CNTs can be fabricated. In a second step, the gaps between the nanotubes can be filled with matrix material. Vapor deposition can be used for either or both steps. The CNTs can be processed so that they are sufficiently open and provide for fluid flow. In some cases, the filling step can be carried out when the CNTs are closed, but then the CNTs can be subsequently opened by for example etching.

If desired, CNTs can be removed by for example oxidation to leave open channels free of or substantially free of CNTs. Vapor deposition can be used by methods known in the art and described in the working examples below. The CNTs can be grown on a substrate containing metallic nanoparticles or metallic layers. For filling the gaps between the CNTs, vapor deposition can be used including chemical vapor deposition.

In some embodiments, CNTs are substantially aligned and span the whole membrane thickness. These membranes may be made using CNTs that get aligned on a substrate during CVD synthesis. CNTs are functionalized after being embedded in a matrix.

In some embodiments, CNTs are randomly dispersed in a matrix and the molecular flow partially happens through CNTs and partially through the matrix. These membranes can be made using unaligned bulk CNTs that are dispersed into a matrix. The functionalization of CNTs can be performed before they are embedded into the matrix. The matrix in this case can be semi-permeable for molecules, retaining some and letting others go through. The permeability of the matrix alone for the molecules of interest can be low. The addition of dispersed CNTs provide high flux channels for molecular transport that enhance the permeability of the membrane at least 2× and up to 100× compared to membranes without CNTs. Functional groups on CNTs serve two purposes for these membranes: 1) they improve membrane selectivity and 2) they enable better dispersion of CNTs in a matrix, allowing for higher CNT density and enhanced permeability.

In yet another embodiment, the CNTs are dispersed in such a way that the CNTs are longer than the thickness of the film. In this embodiment, bulk CNTs are added to the polymer before membrane fabrication. As the result of the process, CNTs are randomly oriented in the membrane, which causes a significant portion of the nanotubes to span the whole membrane thickness. Membrane etching on both sides then produces a permeable membrane. In some embodiments, the top surface of the CNT array can be coated with a protective layer (skin layer), such as fast depositing parylene (PA) that prevents the CNTs from collapsing into each other during matrix infiltration. In some embodiments, the membrane structure comprises a porous bottom support structure, which acts as a boundary confining surface. Examples of bottom support structure include, but are not limited to, polysulfone (PSF), polyethersulfone (PES), etc. The membrane may be opened by either etching the whole protective parylene layer or just opening the CNT pores on top of the parylene layer. In some embodiments, the transport of the fluid can also go through the fill.

In one aspect, the fabrication sequence of the membrane structure comprises, consists essentially of or consists of the following steps:

a) Functionalized CNTs are dispersed in an aqueous phase (for example, water, m-phenylenediamine etc.) or solvent phase (for example, hexane, trimesoylchloride, etc.);

b) PSF membrane support can be dipped into the aqueous phase;

c) excess aqueous solution can be removed from the surface of the membrane support;

d) the membrane support can be dipped into the solvent phase;

e) the membrane support can be cured at the oven; and

f) stored in water.

In some aspects, an electric field can be used to align the CNTs for membrane fabrication. This procedure uses the conducting nature of CNTs or a fraction of CNTs. The application of electric field (either a DC or AC field) results in the induced torque on the CNTs that orients them parallel to the E-field lines. Thus at least a large portion of the CNTs in the matrix becomes oriented. Then the matrix can be cured to permanently immobilize the CNTs in the aligned orientation. The curing methods include, but are not limited to, heat, radical polymerization, UV cure or the like.

In some embodiments, the fabrication sequence of the membrane structure using an electric field comprises, consists essentially of or consists of the following steps:

a) chemically-modified SWNTs (for example, amine) are dispersed in a solvent (for example, THF);

b) the dispersed SWNT solution can be mixed with a polymer (for example, epoxy);

c) the mixture can be magnetically stirred;

d) Indium Tin Oxide (ITO) glass coated with thin polyvinyl acetate (PVA) layer can be prepared (that allows for release of the structure in water);

e) the SWNT/polymer solution can be dropped between ITO glasses;

f) AC electric field can be applied; and

g) after curing or evaporation of the solvent, the assembly can be put into water bath to remove PVA layer and separate SWNT/polymer film from ITO glass.

In yet another embodiment, there can be provided a membrane structure and a fabricaton sequence of the membrane structure using a vapor phase infiltration of carbon nanotube array with parylene polymer fill. In this embodiment, the nanotube array can be coated by polymeric material deposited from vapor phase (for example, parylene) to fill the space between the nanotubes to create a matrix that holds the nanotubes together and precludes mass transport through that filled layer through any other channels except the inner pores of CNTs. The filled CNT layer can then be released from the substrate to form a free-standing membrane that can then be etched from both sides to form a permeable membrane.

Other embodiments for making the membranes are described below. Without limited by any theory, the order of one or more steps may be altered in the methods of making the membrane described herein.

In one aspect, there can be provided a method of making a membrane containing:

a) fabricating a substantially vertically-aligned array of CNTs wherein the nanotubes have average pore size of about 2 nm or less, and wherein the array comprises gaps between the CNTs;

b) filling the gaps between the nanotubes with a ceramic matrix material;

c) opening the nanotubes providing flow through the membrane; and

d) functionalizing a tip of the nanotube with a functional group.

In another aspect, there can be provided a method of making a membrane for enhanced fluid transport containing:

a) providing a substantially vertically-aligned array of CNTs wherein the nanotubes have average pore size of about 2 nm or less;

b) disposing a matrix material between the CNTs;

c) opening the nanotubes providing flow through the membrane; and

d) functionalizing a tip of the nanotube with a functional group.

In another aspect, there can be provided a method for fabricating nanoporous membranes containing:

a) growing a substantially vertically aligned carbon nanotube array on a substrate with high aspect ratio gaps between the nanotubes wherein the nanotubes have average pore size of about 2 nm or less;

b) coating the array with a conformal matrix material capable of conformably filling the high aspect ratio gaps between the nanotubes to immobilize the nanotubes upon hardening of the conformal matrix material;

c) opening the ends of the nanotubes; and

d) functionalizing a tip of the nanotube with a functional group.

In yet another aspect, there can be provided a method of making a membrane containing:

a) fabricating a substantially vertically-aligned array of CNTs, wherein the nanotubes have average pore size of about 2 nm or less and wherein the array comprises gaps between the CNTs;

b) filling the gaps between the nanotubes with polymeric matrix material;

c) opening the nanotubes providing flow through the membrane; and

d) functionalizing a tip of the nanotube with a functional group.

In some embodiments, the fabrication step comprises vapor deposition. In some embodiments, the filling step comprises vapor deposition. In some embodiments, the fabrication step comprises vapor deposition, and the filling step comprises vapor deposition.

In some embodiments, the fabrication step comprises providing a substrate surface containing metal nanoparticle catalyst for vapor deposition. In some embodiments, a thin metal multilayer deposited on silicon can be used as the substrate to catalyze the growth. In some embodiments, the thin metal multilayer may be Fe. In some embodiments, the thin metal multilayer has a thickness of about 5 nm to about 10 nm.

In some embodiments, the filling step comprises chemical vapor deposition. In some embodiments, the filling step comprises vapor deposition when the CNTs are capped.

In some embodiments, the methods further comprise etching on both sides of the membrane to open the CNTs. In some embodiments, the methods further comprise removing the CNTs.

In some embodiments, the methods further comprise removing the nanotubes after hardening of the matrix material. In some embodiments, the nanotubes are removed by oxidation.

In some embodiments, acetylene, ethylene, hydrogen, and argon are used as process gases for growing the nanotube array. Without limited by any theory, any carbon containing gas may be used in this process.

In some embodiments, the conformal material can be silicon nitride. In some embodiments, the conformal material can be TEOS oxide.

In some embodiments, the CVD can be used for the coating process. In some embodiments, the ALD can be used for the coating process.

In some embodiments, the nanotubes are opened by removing excess matrix material from the membrane. In some embodiments, the excess matrix material can be removed from the membrane using a plasma etching process.

In some embodiments, the polymeric matrix material comprises parylene.

### Water Desalination

Further described herein are water flow measurements through microfabricated membranes with sub-6 nanometer (inner diameter) aligned functionalized CNTs as pores. The measured water flow exceeds values calculated from continuum hydrodynamics models by more than two orders of magnitude and can be comparable to flow rates extrapolated from molecular dynamics simulations. The gas and water permeabilities of these nanotube-based membranes are several orders of magnitude higher than those of commercial polycarbonate membranes, despite having order of magnitude smaller pore sizes.

The membranes can be used in a wide variety of applications including for example water desalination, water demineralization, gas separation including removal of hydrocarbons, carbon dioxide sequestration, dialysis, and breathable material for protection from chemical and biological agents.

Both charge and size effects can impact exclusion. The nanotubes are charged at the end with positive or negative charges so that charged particles can be repulsed or attracted to the nanotubes. Charge prevents ions from entering the nanotube which might otherwise enter the nanotube if not for the charge.

Membranes can be used on substrates including for example silicon or glass substrates, as well as porous substrates. Another application can be for use as a high capacity adsorbent material.

The membranes provided herein can be used in various fluid or liquid separation methods, for example, water purification, demineralization, and desalination. For a general review of desalination procedures see “Review of the Desalination and Water Purification Technology Roadmap” available from the United States Bureau of Reclamation, United States Department of the Interior. See also for example U.S. Pat. Nos. 4,302,336; 4,434,057; 5,102,550; 5,051,178; and 5,376,253.

The CNT membranes can operate on the basis of both size and charge screening (Donnan exclusion and Coulombic repulsion) effects. Although many conventional membranes rely on both effects, a novelty point for this CNT membrane lies in the higher water flux achievable under conventional operating pressures. While the present embodiments are not limited by theory, some principles are noted. The nanometer size of CNTs (for example, 0.5-6 nm), which approaches that of many solvated ions of interest to desalination process, suggests that many species may be unable to enter the nanotube and make it across the membrane. Indeed, recent molecular dynamics simulations of osmotic water transport through carbon nanotube membranes (Karla et al. (2004) PNAS 100(18):10175) suggest that 0.8 nm diameter CNTs are sufficient to block species as small as hydrated Na⁺ and Cl. Yet another screening effect can be caused by charge layer overlap at the “mouth” of the nanotube pore where charges are present (Miller et al. (2001) JACS 13(49):12335).

In electrolyte solutions, counterions present (those of opposite charge to the functional groups on the membrane surface) to balance these tip charges. Under the appropriate ionic strength and pore size, an overlap of these counterion charge layers occurs. The net effect of this can be the creation of an “ion gate” that may exclude co-ions of like charge with the functional groups and only permit counterions to pass through the channel. As a result, the CNT membrane can be designed for cation (for acid functionality) or anion (for base functionality) transmission. A characteristic of this type of exclusion can be a dependency on the co-ion valency. For example, for a base-functionalized membrane (carrying positive charge), species such as Ca²⁺ and Mg²⁺ may be rejected to a greater extent than monovalent species like Na⁺ and K⁺ (Yaroshchuk, A. (2001) Sep. and Purification Tech. 143:22-23).

High water permeability for the proposed membrane can be carried out and the results interpreted in view of several studies (for example, Kahn et al. (2004) PNAS 100(18):10175; Hummer, G. (2001) Nature 414:188; Koga, et al. (2001) Nature 412:802) that have predicted high water flux through SWCNTs. The high flux predictions are partly a consequence of inherent atomic nanotube interior, which leads to nearly frictionless transport. Another factor, which appears to be unique to the non-polar CNT/polar molecule system, relates to molecular ordering that can occur on this nanometer scale. These molecular dynamic simulations (Kahn et al. (2004) PNAS 100(18):10175; Hummer, G. (2001) Nature 414:188; Koga, et al. (2001) Nature 412:802) have suggested one-dimensional ordering of water molecules confined within CNTs, leading to single hydrogen bonds between them. These so-called “water wires”, which are of relevance in biological systems (Rouseau, et al. (2004) Phys. Chem. Chem Phys. 6:1848), are able to shuttle in and out of the carbon nanotube channels rapidly as a consequence of their ordering and non-interaction with the pore walls. Recent experiments using neutron diffraction have indeed confirmed the existence of these “water wires” within carbon nanotube pores (Kolesnikov, A. (2004) Phys. Rev. Lett. 93: 035503-1), suggesting that the predicted rapid transport rates may be experimentally observable.

Water desalination can be carried out by passing the water through multiple membranes to produce purification which removes for example at least 50 mole percent, or at least 60 mole percent, or at least 70 mole percent, or at least 80 mole percent, or at least 90 mole percent of the target molecule or ion such as for example chloride or sodium.

### Electrosorption of Cr^{III}

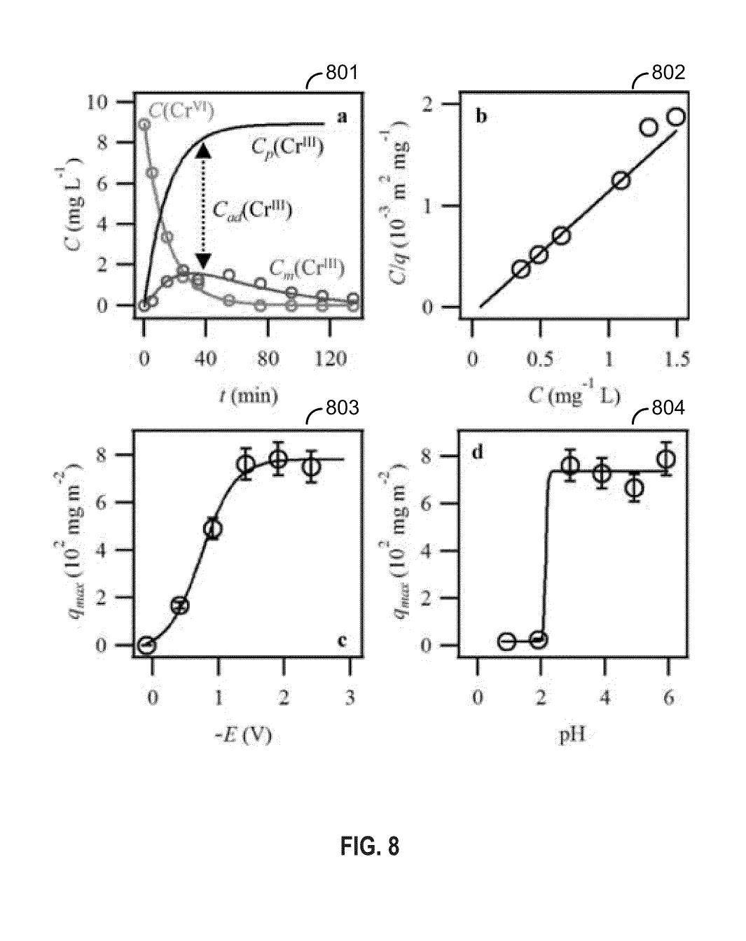

As illustrated in FIG. 8, compared to Cr^{VI}, the concentration of the reduction product Cr^{III} shows a complex time dependence. Regarding the electrosorption of Cr^{III}: graph 801 illustrates changes of Cr^{IV} and Cr^{III} concentrations with time, graph 802 illustrates conformation to the Langmuir isotherm (pH 3), graph 803 illustrates dependence on potential and graph 804 illustrates dependent on pH. Solution: K₂Cr₂O₇, 9 mg L⁻¹; volume, 100 mL. Electrode: L=14(±1) μm. Potential: E=−1.4 V. The Cr^{III} concentration first increases with time, reaches a maximum around t=30 min, and decreases to nearly zero (see graph 801). Furthermore, the measured Cr^{III} concentration can be much lower than the concentration predicted by the stoichiometry of reaction 1. The difference between the predicted and measured concentrations (Cₚ and Cₘ) to the electrosorption of Cr^{III} cations such as Cr³⁺ and Cr(OH)²⁺ by the negatively polarized electrode:

C_{ad}(Cr^{III})=Cₚ(Cr^{III})−Cₘ(Cr^{III}) (8)

Where Cₚ=C₀(Cr^{VI})−C(Cr^{VI}). The electrosorption of Cr^{III} is the second step of Cr removal. The amount of Cr^{III} adsorbed per unit of GSA can then be calculated as:

q=C_{ad}V/GSA (9)

A linear correlation can be found between C/q and q for t>30 min, suggesting that the electrosorption of Cr^{III} conforms to the classical Langmuir isotherm (see graph 802):

$$\frac{C}{q} = \frac{C}{{q}_{max}} + \frac{1}{{q}_{max} {K}_{s}} \qquad ( 10 )$$

where qₘₐₓ is the maximum sorption capacity, and Kₛ is the equilibrium constant. The conformation to equation 10 suggests that the electrosorption of Cr^{III} can be considered as an equilibrium-controlled process at least after 30 min. In addition, the linearity has a near zero intercept, consistent with a large value for Kₛ that favors the partitioning of Cr^{III} cations on the electrode rather than staying in solution. Comparisons of qₘₐₓ values obtained at different potential and pH conditions show that qₘₐₓ increases with increasing −E and pH, approaching a maximal value of 746(±44) mg m⁻² for −E≧1.4 V and pH≧3 (see graphs 803 and 804). The dependence of qₘₐₓ on −E suggests that electrostatic attraction controls Cr^{III} electrosorption at small polarization, which becomes limited by the availability of Cr^{III} when polarization is sufficiently negative. The dependence of qₘₐₓ on pH suggests that proton competes with Cr^{III} in electrosorption and the competition diminishes as the proton concentration decreases.

Effects of ESA on Cr^{VI} Reduction and Cr^{III} Sorption

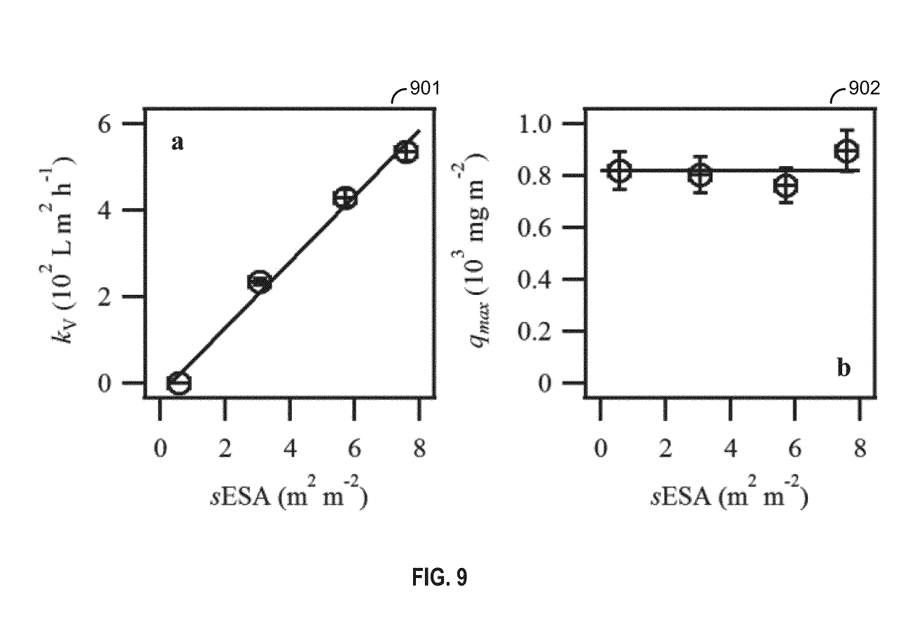

FIG. 9 illustrates the effects of ESA on Cr^{VI} reduction and Cr^{III} sorption by comparing k_{V} and qₘₐₓ values obtained using electrodes with different CNT lengths.

k_{υ}=k_{ESA}×sESA (11)

This suggesting the existence of a surface-normalized constant kESA=76(±5) L m⁻² h⁻¹ at pH 3. Graph 901 illustrates the dependence of volume normalized pseudo-first-order rate constant (k_{V}), and graph 902 illustrates maximum sorption capacity qmax on specific electrochemical surface area sESA. Solution: K₂Cr₂O₇, 9 mg L⁻¹; pH, 3. Potential: E=−1.4 V. Similar to the ferric-to-ferrous reduction, the reduction of Cr^{VI} to Cr^{III} can be rapid at the electrode—solution interface. The overall reduction rate can be controlled by the transfer of negatively charged chromate and dichromate anions to the negatively charged electrode. Different from k_{V}, qₘₐₓ can be insensitive to the change of ESA and has an average value of 820(±28) mg m-2 (graph 902), suggesting that electrosorption can be not controlled by ESA and thus not by mass transfer. This can be consistent with the mechanism of electrosorption of cations by a negatively polarized electrode, which can be controlled by the strength of the electrical field and the presence of competing ions.

### Regeneration of Electrode and Recollection of Cr^{III}

The dependence of qₘₐₓ on pH also suggests that adsorbed Cr^{III} can be readily removed in an acidic solution, providing a method for recycling chromium and regenerate the electrode. The removal process can be further promoted by reversing the potential on the CNT electrode from being negative to being positive. FIG. 6 illustrates recollection of adsorbed Cr^{III} and regeneration of the CNT electrode. Solutions: I and III, 100 mL K₂Cr₂O₇ at pH 3; II, 30 mL 0.1 M H₂SO₄. Electrode: L=14(±1) μm. Potential: I and III, −1.4 V; II, 1.0 V. First, the electrochemical treatment was performed with 100 mL of aqueous solution containing 12 mg L⁻¹ Cr^{VI} at pH 3 and operated at E₀=−1.4 V. After 115 min, 96% of Cr^{VI} was reduced to Cr^{III}, which was in turn adsorbed by the electrode. Second, the electrode was immersed in 30 mL of pH 1 aqueous solution, and the potential on the electrode was reversed to E=1.0 V. In 90 min, 97% of the adsorbed Cr^{III} desorbed from the electrode, as confirmed by the measurement of Cr^{III} concentration in the recycling solution. Third, the regenerated electrode was used to treat the same Cr^{VI}-containing solution, exhibiting performance similar to that of the new electrode with 96% removal in 115 min.

### Carbon Nanotube Length

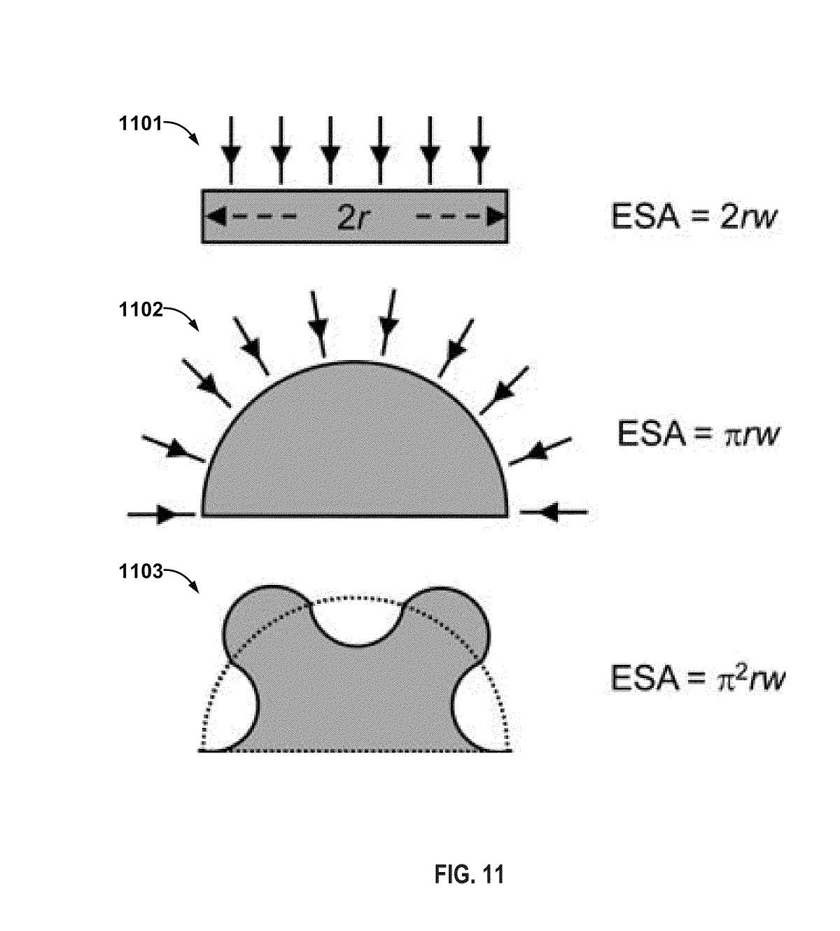

The linear correlation of kV and sESA suggests that increasing ESA can be beneficial to the electrochemical removal of Cr^{VI}, whose kinetics can be controlled by Cr^{VI} reduction. The asymptotic relationship between sESA and L suggests that sESA can reach a maximum value of 15.1(±0.7) m² m⁻² with infinitely long CNTs. In synthesis, the CNT length can be limited by the longevity of the growth catalysts, which aggregate and coalesce under the high temperature of CVD. A value of sESA=7.6(±0.3) m² m⁻² may be achieved by growing CNTs in CVD for 30 min. This sESA can be more than 3 times greater than the values achieved previously for CNT electrodes prepared with both vertically aligned and randomly attached CNTs. Further increase of synthesis time can be found not to further increase the length of VACNTs. Instead, amorphous carbon can be formed due to the deactivation of the Fe/Ni nanoparticles on SSM. At least two geometric factors may have contributed to the increase of sESA as L increases, including (1) filling of the void spaces left by the SSM openings and (2) creation of curved surfaces. SSM has an sESA of 0.6(±0.3) m² m⁻², consistent with the specific cross-section area of SSM: [(25+38)2−382]/(25+38)2=0.635 m² m⁻². Both values are smaller than the specific surface area of a plate electrode (sESA=1 m² m⁻²). Growing CNTs fills up the void space and thus improves sESA to unity. Further increase of sESA from 1 to 7.6(±0.3) m² m⁻² can be attributed to the curvature of individual CNTs and the filling of the space between them. The curvature effect can be illustrated in FIG. 11.

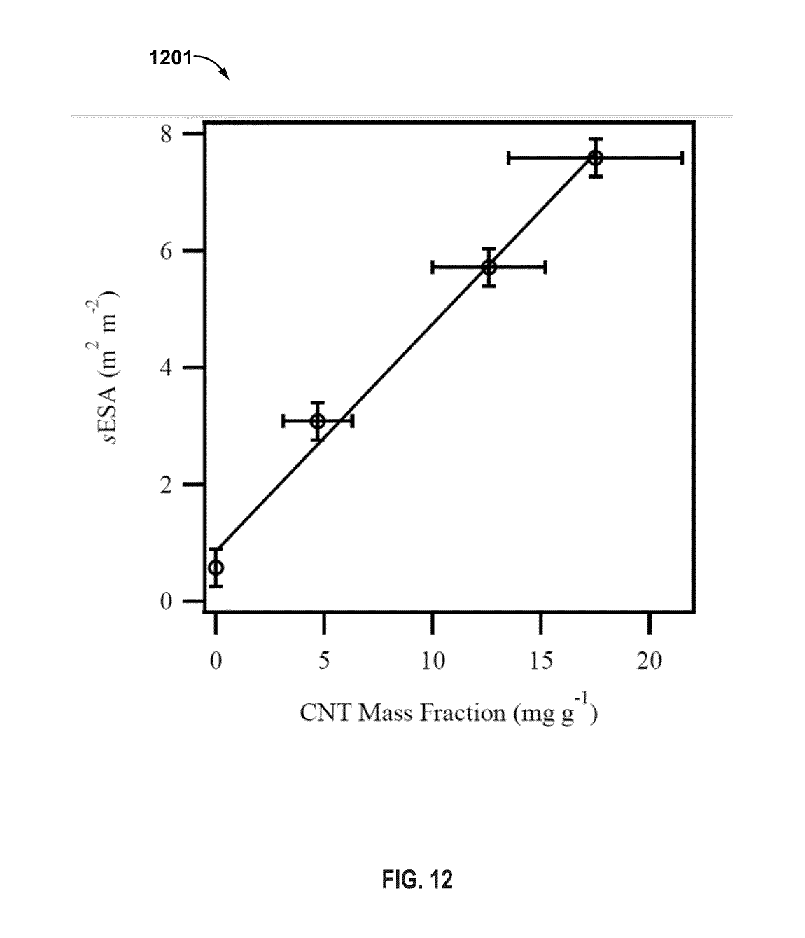

Specifically, FIG. 11 illustrates increasing electrochemical surface area (ESA) by increasing electrode surface roughness. For example, plate electrode 1101, half-sphere electrode 1102, and half-sphere electrode with surface being further divided by smaller half spheres 1103. A square plate electrode with a flat surface intersects with the electrical field lines normally (1101). This gives an ESA equivalent to its geometrical surface area defined by length 2r and width w of the plate: 2rw. Replacing the plate with a half cylinder having radius r increases the area of the receiving surface. To intersect normally with the curved receiving surface, field lines are bent near the electrode surface (1102). This increases ESA to πrw while maintaining the same GSA (note: by definition, GSA can be always associated with the plate geometry), giving sESA=π/2. The surface of the half cylinder can be further divided by smaller half cylinders (1103), which further increases sESA to π2/2. Repeating this operation for n times, sESA=πn/2. To obtain a 7.6-times increase of sESA, a value of substantially n=2.4 may be sufficient. This analysis can be consistent with the understanding that increasing the roughness of an electrode surface increases sESA. Growing VACNTs adds roughness to the otherwise flat SSM surface. The roughness originates from both the large number of CNTs and the curvature of individual CNTs (105). Because individual CNTs are spaced from each other, contributions to roughness and thus sESA come from not only the very top portion of a CNT but also a large portion in the middle of the nanotubes. As a result, longer CNTs contribute more to sESA although the curvature of CNTs and the porosity of CNT arrays remain constant regardless of CNT length (see, FIG. 5). This can be equivalent to state that sESA increases proportionally with the increase of CNT mass fraction, as supported by measurements 1201 (see, FIG. 12).

FIG. 12 illustrates a correlation of the specific electrochemical surface area of CNT electrodes and their CNT mass fraction 1201 (fraction of CNT mass in the total mass of CNTs and SSM). The solid line represents a least-square regression, giving a slope of 0.85(±0.28) with R²=0.99. As CNTs grow longer, however, the area between individual CNTs that can be projected the surface to receive the electrical field lines begins to fill up, leading to a limiting sESA. The large sESA makes CNT electrodes particularly advantageous for removing recalcitrant contaminants such as Cr^{VI}. With L=24 μm and sESA=7.6 m² m⁻², k_{V}=810 L m⁻² h⁻¹ at pH 1, which can be more than 4 times faster than using the polypyrrole-coated carbon electrode. At pH 4, k_{V} can be 250 L m⁻² h⁻¹, which can be approximately an order of magnitude greater than using an SSM electrode randomly coated with single-walled CNTs.

The carbon nanotube electrodes disclosed herein are prepared by growing vertically aligned CNT arrays directly on stainless steel mesh. Compared to randomly orientated CNTs, VACNTs provides a high grafting density with a high degree of roughness and good electrical contact. As shown herein, compared to SSM, growing VACNTs can increase ESA by more than an order of magnitude. The increased ESA can directly benefit Cr^{VI} reduction by proportionally accelerating the reduction reaction without compromising the ability for CNTs to adsorb Cr^{III}. The overall efficiency of chromium removal can be maximized by operating near pH 3 and at E=−1.4 V. Furthermore, the adsorbed Cr^{III} can be readily recollected by acid wash, which also regenerates the electrode.

### Methods

All chemicals were of analytical grade, purchased from Sigma-Aldrich and used as received without further purification. Deionized (DI) water (18.2 MΩ cm⁻¹) was generated on site using a Millipore ultrapure water system. The AISI 304 SSM with a mesh size of 400×400 openings per square inch.

### Fabrication of Carbon Nanotube Electrode

A piece of 5×5 cm SSM was cleaned by sonication in acetone for 15 min and then dried by blowing pure nitrogen gas. The cleaned mesh was rolled and inserted into a 1 in. quartz tubing housed in a horizontal furnace. The furnace was heated to 500° C. in 15 min and held at that temperature for another 15 min to break the chromium-oxide passivation layer and generate iron and nickel catalytic nanoparticles. The temperature was then ramped to 700° C. in 5 min under the flow of 300 sccm argon. Once the temperature was stabilized, 20 sccm acetylene and 150 sccm hydrogen were introduced into the quartz tubing to initiate CNT growth. After 10-30 min, the furnace was cooled to the ambient temperature under the protection of argon before the sample was removed from the quartz tubing.

### Characterization of Carbon Nanotube Electrode

Physical properties of SSM and CNT electrodes were characterized using scanning electron microscopy (FEI Magellan 400), transmission electron microscopy (FEI Titan 80-300), Raman spectroscopy (Renishaw 1000), and the BET surface area analysis (Micromeritics ASAP 2000). Because the specific surface areas of CNT electrodes are too small for direct measurements with the BET analyzer, CNT arrays were scratched off SSM using a razor blade. The ESA of the electrode was measured using a three-electrode potentiostat (CHI 610D) and a testing solution of ferric cyanide at room temperature. A piece of SSM or CNT electrode (1×0.2 cm), a platinum sheet of the same size, and the Ag/AgCl electrode were used as the working, counter, and reference electrodes, respectively. The solution contains 5 mM potassium ferricyanide and 0.1 M potassium nitrate.

### Electrochemical Removal and Recollection of Chromium

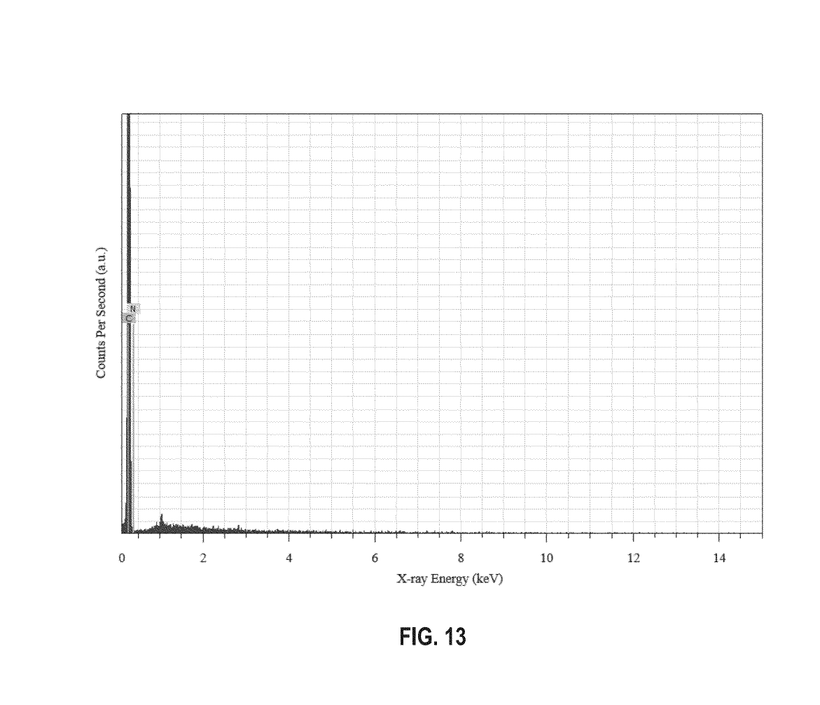

FIG. 13 illustrates an energy dispersive X-ray spectrum of the carbon-paper anode after being used in the electrochemical treatment of chromium. The absence of peaks around 5.5 keV confirms that there may be little chromium, if any, adsorbed on the anode. Conditions for the electrochemical treatment: initial concentration, 9.8 mg L⁻¹; pH, 3; duration, 120 min; potential, −1.4 V; cathode CNT length, L=14(±1) μm.

Experiments were conducted in the batch mode using the potentiostat. The cathode was either a CNT or SSM electrode (3×3 cm), a piece of carbon paper (Fuel Cell Earth LLC, Stoneham, Mass.) of the same size as the anode, and the Ag/AgCl electrode as reference. The carbon paper was used, instead of a platinum electrode, to prevent the oxidation of Cr^{III} back to Cr^{VI}. The carbon paper did not adsorb Cr^{VI} (see, FIG. 13), likely due to the large size of its anions and the lack of functional groups on the paper's surface. The cathode and anode were separated by a 3 cm gap. FIG. 13 illustrates an energy dispersive X-ray spectrum of the carbon-paper anode after being used in the electrochemical treatment of chromium. The absence of peaks around 5.5 keV confirms that there may be little chromium, if any, adsorbed on the anode. Conditions for the electrochemical treatment: initial concentration, 9.8 mg L⁻¹; pH, 3; duration, 120 min; potential, −1.4 V; cathode CNT length, L=14(±1) μm. A potential (with respect to the standard hydrogen electrode) was applied between the cathode and the reference electrode while the current generated by this potential passes through the anode, forming a three-electrode system.

The experiments were performed with 100 mL K₂Cr₂O₇ aqueous solution containing 10 g L-1 Na₂SO₄ as the supporting electrolyte. The solution pH was adjusted using concentrated NaOH or H₂SO₄ solutions and confirmed with a pH meter (Fisher Scientific). During experiments, the solution was stirred constantly with a magnetic stirrer to maintain homogeneity. After potential was applied between cathode and anode to initiate reaction, 0.2 mL solution was withdrawn periodically for measurement. Half of the solution was mixed with diphenylcarbazide, which reacted with Cr^{VI} to produce a strong pink color. The intensity of the color was measured using a UV/vis spectrophotometer (Agilent Cary 300), which gave the Cr^{VI} concentration through Beer's law. To determine the concentration of Cr^{III}, the other half of the sample was oxidized with an excess amount of potassium permanganate (KMnO₄) to convert Cr^{III} to Cr^{VI}. The concentration of Cr^{VI} was again determined colorimetrically. The Cr^{III} concentration was computed by subtracting the first Cr^{VI} concentration from the second Cr^{VI} concentration.

To study the effects of solution volume, solution chemistry, and electrode surface area on Cr^{VI} reduction and Cr^{III} adsorption, the corresponding experimental condition may be varied while all other conditions are kept constant. For example, to investigate the volume effect, the K₂Cr₂O₇ concentration, the Na₂SO₄ concentration, and pH at 10 mg L⁻¹ may be fixed, while the solution volume may be varied from 50 to 200 mL.

The recollection of Cr^{III} adsorbed by CNTs was performed in 0.1 M sulfuric acid. The Cr^{III} concentration in the recollection solution was determined colorimetrically after the solution being completely oxidized by KMnO₄. The amount of recollected Cr^{III} was then computed by multiplying the Cr^{III} concentration with the volume of H₂SO₄ solution used to perform recollection.

### Filtering Mechanism

A filtering mechanism may be used in conjunction with the VACNTs grown on the electrode. For example, the electrode may be sized and shaped to be positioned in a tube perpendicular to the tubing walls, and held in place with plastic or metal supports. The electrode may also be held using adhesives or magnetic material. In another example embodiment, the electrode may be sized and shaped to a cylindrical, semi-cylindrical, or corkscrew shape designed to line the walls of the tubing for a length of the tube. In yet another example embodiment, the electrode may be sized and shaped in the cylindrical or semi-cylindrical shape discussed above with one or more closed distal ends, similar to a filter sock. In one example embodiment the distal end of the sock can be closed by an end cap made of any suitable material for treatment of waste water. The end cap may be sealed or, in other embodiments, may comprise opening to allow the passage of waste water and the placement of additional VACNT electrodes. The filtering mechanism may include a supply tank containing the waste water to be filtered and a collection tank for receiving therein the filtered water. In another example embodiment, the VACNTs may be grown within a microfluidic channel of a substrate. The CNTs may be grown attached within a microfluidic channel which can be subsequently sealed. The mesh may be grown to completely fill a segment of the channel, namely, its cross-section can be filled, or grown to surface-coat a segment of the channel without completely filling the segment, so as to produce a gap through the segment. CNT structural parameters of height, density, and pore size may be regulated and controlled by changing gas flows, flow ratios, and catalyst thickness.

In one example embodiment, the waste water may be supplied from the storage tank to a centrifugal filter device, the filter including a configuration of VACNTs which are effective in removing contaminating particles from the waste water, with the filtered liquid then being discharged into a collection tank. The centrifugal filter device may include a rotatable drumlike filter unit which rotates substantially about a vertical, horizontal, or diagonal axis, and has the waste water deposited in the interior thereof. In one embodiment, the cylindrical sidewall of the filter unit may a filter pad associated therewith which removes contaminants from the waste water as the waste water can be forced radially through the pad due to centrifugal force. The waste water may flow into the filter unit with the aid of pumps or through a gravity fed system. The filtered liquid collects in a casing which surrounds the rotating filter unit and flows by pump or gravity into the collection tank. The filter unit, in an embodiment, has a plurality of angularly spaced, circular openings formed through the sidewall of the drumlike casing, with each opening being covered by a VACNT configuration described herein. The screens and filter may be held in place by a removable cap, adhesive, magnetic material, hardware fastener, or something similar.

In another example embodiment, the above-described filter system can be integrated with a recirculation machine so that the liquid in the collecting tank can be recirculated back into the storage tank for additional filtering. The flow of liquid from the storage tank to the filtering mechanism may be controlled using a manual or electronic shutoff valve, or both. In one example embodiment, the flow of liquid from the storage tank may be shut off to allow an acidic solution to flow through the filtering mechanism. The recollection of Cr^{III} absorbed by the CNTs can be readily performed by an acid wash. In one example embodiment, the acidic solution may include 0.1 M sulfuric acid, which can also regenerate the electrode.

In another example embodiment, a monitor may be integrated with the filtering mechanism to allow for measuring the concentration of various forms of contaminants. In one example, the filtering mechanism may include a UV/vis spectrophotometer that can provide a given contamination level through Beer's law. In one example, an amount of diphenylcarbazide may be added to the filtered waste water, and the resulting color measured and provided using the contamination level in the liquid. In another example, the monitor may include a sample cell, a light source, and a photodetector. The sample cell can be in the form of a liquid-core waveguide defining an interior core and acting as a receiver for the liquid to be analyzed, the interior surface of the sample cell having a configurable refractive index. The light source may be in communication with a first end of the sample cell for emitting radiation having a configurable wavelength into the interior core of the waveguide. The photodetector can be in communication with a second end of the waveguide for measuring the absorption of the radiation emitted by the light source by the liquid in the sample cell. The monitor may also include a processor electronically coupled to the photodetector for receipt of an absorption signal to determine the concentration of contaminants in the liquid.

In one example embodiment, the monitor may be electronically coupled to a valve controlling the flow of filtered liquid back to the storage tank. When the monitor has determined that the contaminants in the liquid have been reduced to below a configurable maximum level, the filtered liquid may be flowed into the collecting tank.

While the disclosure has been illustrated and described in detail in the drawings and foregoing description, such illustration and description are to be considered illustrative or exemplary and not restrictive. The disclosure can be not limited to the disclosed embodiments. Variations to the disclosed embodiments can be understood and effected by those skilled in the art in practicing the claimed disclosure, from a study of the drawings, the disclosure and the appended claims.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein. It should be noted that the use of particular terminology when describing certain features or aspects of the disclosure should not be taken to imply that the terminology is being re-defined herein to be restricted to include any specific characteristics of the features or aspects of the disclosure with which that terminology is associated. Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘comprising’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide exemplary instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular embodiment of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

Where a range of values is provided, it is understood that the upper and lower limit, and each intervening value between the upper and lower limit of the range is encompassed within the embodiments.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity. The indefinite article “a” or “an” does not exclude a plurality. A single processor or other unit may fulfill the functions of several items recited in the claims. The mere fact that certain measures are recited in mutually different dependent claims does not indicate that a combination of these measures cannot be used to advantage. Any reference signs in the claims should not be construed as limiting the scope.

It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (for example, “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (for example, the bare recitation of “two recitations,” without other modifiers, typically means at least two recitations, or two or more recitations). Furthermore, in those instances where a convention analogous to “at least one of A, B, and C, etc.” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, etc.). In those instances where a convention analogous to “at least one of A, B, or C, etc.” is used, in general such a construction is intended in the sense one having skill in the art would understand the convention (for example, “a system having at least one of A, B, or C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific embodiments and examples described herein, but rather to also cover all modification and alternatives coming with the true scope and spirit of the invention.

What is claimed is:

1. A composition for removing heavy metals from wastewater, comprising:
a binder-free electrode comprising, an oxide buffer layer, a substrate comprising a material constructed in a pattern, and a layer of catalyst nanoparticles; and
an array of vertically aligned carbon nanotubes grown on the electrode.

2. The composition of claim 1, further comprising a negatively polarized electrode configured to provide electrons for Cr^{VI} reduction and Cr^{III} absorption through electrostatic attraction.

3. The composition of claim 1, wherein the oxide buffer layer is an aluminum oxide.

4. The composition of claim 1, wherein the oxide buffer layer is formed by immersion of the substrate in both (a) a polyacrylic acid solution, and (b) a boehmite (γ-AlOOH) nanoplate suspension.

5. The composition of claim 1, wherein the substrate comprises a porous stainless steel mesh, the stainless steel mesh comprising a plurality of stainless steel wires, the wires having a curved surface.

6. The composition of claim 1, wherein a layer of the catalyst nanoparticles are deposited on the oxide buffer layer.

7. The composition of claim 1, wherein the catalyst nanoparticles comprise magnetite (Fe₃O₄) nanoparticles.

8. A method of manufacturing a composition, comprising:
cleaning a substrate;
coating the substrate with the oxide buffer;
depositing a layer of catalyst nanoparticles onto the oxide buffer layer layer, whereby a binder-free electrode is obtained; and
growing an array of vertically aligned carbon nanotubes on the binder-free electrode, whereby the composition of claim 1 is obtained.

9. The method of claim 8, further comprising negatively polarizing the binder-free electrode to provide electrons for Cr^{VI} reduction and Cr^{III} absorption through electrostatic attraction.

10. The method of manufacturing of claim 8, wherein the oxide buffer layer is an aluminum oxide.

11. The method of manufacturing of claim 8, wherein the oxide buffer layer is formed by immersion of the substrate in both (a) a polyacrylic acid solution, and (b) a boehmite (γ-AlOOH) nanoplate suspension.

12. The method of manufacturing of claim 8, wherein the oxide buffer layer is deposited on the substrate using a wet chemistry method.

13. The method of manufacturing of claim 8, wherein the substrate comprises a porous stainless steel mesh, the stainless steel mesh comprising a plurality of stainless steel wires, the wires having a curved surface area.

14. The method of manufacturing of claim 8, wherein the catalyst nanoparticles comprise magnetite (Fe₃O₄) nanoparticles.

15. A method of removing heavy metals from wastewater, the method comprising:
providing the binder-free electrode with vertically aligned carbon nanotubes of claim 1; and
exposing a wastewater comprising Cr^{VI} to the binder-free electrode with vertically aligned carbon nanotubes, whereby Cr^{VI} is reducted to Cr^{III}.

16. The method of claim 15, further comprising negatively polarizing the electrode to provide electrons for Cr^{VI} reduction and Cr^{III} absorption through electrostatic attraction.

17. The method of claim 15, wherein the oxide buffer layer is an aluminum oxide.

18. The method of claim 15, wherein the oxide buffer layer is formed by immersion of the substrate in both (a) a polyacrylic acid solution, and (b) a boehmite (γ-AlOOH) nanoplate suspension.

19. The method of claim 15, wherein the substrate comprises a porous stainless steel mesh, the stainless steel mesh comprising a plurality of stainless steel wires, the wires having a curved surface area.

20. The method of claim 15, wherein the catalyst nanoparticles comprise magnetite (Fe₃O₄) nanoparticles.
